(19) United States
(12) Patent Application Publication
(10) Pub. No.: US 2023/0307583 A1
(43) Pub. Date: Sep. 28, 2023

(54) DISPLAY DEVICE

(71) Applicant: Samsung Display Co., LTD., Yongin-si (KR)

(72) Inventors: Sung Chul HONG, Yongin-si (KR); Kyung Bae KIM, Yongin-si (KR); Do Yeong PARK, Yongin-si (KR)

(21) Appl. No.: 18/070,329

(22) Filed: Nov. 28, 2022

(30) Foreign Application Priority Data
Feb. 10, 2022 (KR) 10-2022-0017683

(51) Int. Cl. H01L 33/38; H01L 33/62; H01L 25/075

(52) U.S. Cl. CPC H01L 33/387; H01L 25/0753; H01L 33/62

(57) ABSTRACT

A display device includes pixels, and the pixels include: alignment electrodes provided on a base layer; a light emitting element provided on the alignment electrodes; and connection electrodes electrically connected to the light emitting element. The connection electrodes are electrically connected to some of the alignment electrodes through contact portions, and the number of the contact portions defined in each of the pixels is less than the number of the alignment electrodes.

### CROSS-REFERENCE TO RELATED APPLICATION

The application claims priority to and the benefit of Korean Patent Application No. 10-2022-0017683, filed Feb. 10, 2022, the entire content of which is hereby incorporated by reference.

### BACKGROUND

### 1. Field

One or more embodiments of the present disclosure relate to a display device.

### 2. Description of the Related Art

In recent years, as interest in information displays is increasing, research and development on display devices are continuously conducted.

### SUMMARY

Aspects of one or more embodiments of the present disclosure are directed toward provide a display device in which a manufacturing process is simplified and noise with respect to an electrical signal and resistance of a wiring are reduced.

According to one or more embodiments of the disclosure, a display device may include pixels, and the pixels may include: alignment electrodes provided on a base layer; a light emitting element provided on the alignment electrodes; and connection electrodes electrically connected to the light emitting element. The connection electrodes may be electrically connected to some of the alignment electrodes through contact portions, and a number of the contact portions defined in each of the pixels may be less than a number of the alignment electrodes.

According to one or more embodiments, the connection electrodes may include an anode connection electrode and a cathode connection electrode, the light emitting element may be electrically connected between the anode connection electrode and the cathode connection electrode, and the alignment electrodes may be electrically connected to at least one of the anode connection electrode and the cathode connection electrode.

According to one or more embodiments, the anode connection electrode and the cathode connection electrode may include a same conductive layer.

According to one or more embodiments, when the light emitting element emits light, an anode signal or a cathode signal may be provided to the alignment electrodes.

According to one or more embodiments, the alignment electrodes may include a first alignment electrode, a second alignment electrode, a third alignment electrode, a fourth alignment electrode, and a root alignment electrode, and the root alignment electrode, the second alignment electrode, and the third alignment electrode may be integrally formed and may be electrically connected to each other.

According to one or more embodiments, a portion of the cathode connection electrode may be electrically connected to the root alignment electrode, and another portion of the cathode connection electrode may be electrically connected to the fourth alignment electrode.

According to one or more embodiments, the second alignment electrode, the third alignment electrode, and the fourth alignment electrode may be electrically connected to each other.

According to one or more embodiments, when the light emitting element emits light, the alignment electrodes may not be in a floating state.

According to one or more embodiments, when the light emitting element emits light, the alignment electrodes may not be in a floating state, an anode signal may flow through the first alignment electrode, and a cathode signal may flow through the second alignment electrode, the third alignment electrode, and the fourth alignment electrode.

According to one or more embodiments, the connection electrodes may include a first connection electrode, a second connection electrode, a third connection electrode, a fourth connection electrode, and a fifth connection electrode, the alignment electrodes may include a first alignment electrode, a second alignment electrode, a third alignment electrode, and a fourth alignment electrode, and the light emitting element may include a first light emitting element, a second light emitting element, a third light emitting element, and a fourth light emitting element. The first light emitting element may be electrically connected between the first connection electrode and the second connection electrode, and may be aligned between the first alignment electrode and the second alignment electrode. The second light emitting element may be electrically connected between the second connection electrode and the third connection electrode, and may be aligned between the first alignment electrode and the second alignment electrode. The third light emitting element may be electrically connected between the third connection electrode and the fourth connection electrode, and may be aligned between the third alignment electrode and the fourth alignment electrode. The fourth light emitting element may be electrically connected between the fourth connection electrode and the fifth connection electrode, and may be aligned between the third alignment electrode and the fourth alignment electrode.

According to one or more embodiments, the contact portions may include a first contact portion, a second contact portion, and a third contact portion. The first connection electrode may be electrically connected to the first alignment electrode through the first contact portion. The fifth connection electrode may be electrically connected to the second alignment electrode and the third alignment electrode through the second contact portion, and may be electrically connected to the fourth alignment electrode through the third contact portion. The first connection electrode may supply an anode signal to the light emitting element and the fifth connection electrode may supply a cathode signal to the light emitting element so that the light emitting element emits light.

According to one or more embodiments, the fifth connection electrode may overlap the second contact portion and the third contact portion in a plan view.

According to one or more embodiments, the first contact portion, the second contact portion, and the third contact portion may be arranged parallel to a direction in which the first alignment electrode, the second alignment electrode, the third alignment electrode, and the fourth alignment electrode are adjacent to each other.

According to one or more embodiments, when the light emitting element emits light, the anode signal provided through the first connection electrode may be supplied to the light emitting element and the first alignment electrode, and the cathode signal provided through the fifth connection electrode may be supplied to the light emitting element, the second alignment electrode, the third alignment electrode, and the fourth alignment electrode.

According to one or more embodiments, the first connection electrode and the fifth connection electrode may include the same conductive layer.

According to one or more embodiments, the fifth connection electrode may not be electrically connected to (e.g., may be electrically separated from) the fourth alignment electrode.

According to one or more embodiments, when the light emitting element emits light, an anode signal may be supplied to the first alignment electrode, and a cathode signal may be supplied to the second alignment electrode and the third alignment electrode.

According to one or more embodiments, the alignment electrodes may include a bridge alignment electrode, and the bridge alignment electrode may electrically connect the fourth alignment electrode and an adjacent alignment electrode of an adjacent pixel to each other.

According to one or more embodiments, when the light emitting element emits light, an anode signal may be supplied to the first alignment electrode and the fourth alignment electrode, and a cathode signal may be supplied to the second alignment electrode and the third alignment electrode.

According to one or more embodiments of the disclosure, a display device may include alignment electrodes provided on a base layer; a light emitting element provided between the alignment electrodes; and connection electrodes supplying an anode signal or a cathode signal to the light emitting element. When the light emitting element emits light, the alignment electrodes may not be in a floating state and may be supplied with the anode signal or the cathode signal.

### BRIEF DESCRIPTION OF THE DRAWINGS

The accompanying drawings, which are included to provide a further understanding of the present disclosure, and are incorporated in and constitute a part of this specification, illustrate embodiments of the present disclosure, and, together with the description, serve to explain principles of the present disclosure.

FIG. 1 is a perspective view illustrating a light emitting element according to one or more embodiments.

FIG. 2 is a cross-sectional view illustrating the light emitting element according to one or more embodiments.

FIG. 3 is a plan view illustrating a display device according to one or more embodiments.

FIG. 4 is a circuit diagram illustrating a pixel according to one or more embodiments.

FIGS. 5-8 are plan views illustrating pixels according to one or more embodiments.

FIG. 9 is a schematic cross-sectional view taken along the line A-A′ of FIG. 5.

FIG. 10 is a schematic cross-sectional view taken along the line B—B′ of FIG. 5.

FIG. 11 is a cross-sectional view illustrating first to third pixels according to one or more embodiments.

FIG. 12 is a cross-sectional view of a pixel according to one or more embodiments.

### DETAILED DESCRIPTION

As the disclosure allows for various changes and numerous embodiments, certain embodiments will be illustrated in the drawings and described in more detail in the written description. However, this is not intended to limit the disclosure to particular modes of practice, and it is to be appreciated that all changes, equivalents, and substitutes that do not depart from the spirit and technical scope of the disclosure are encompassed in the disclosure.

It will be understood that, although the terms “first”, “second”, etc. may be used herein to describe various elements, these elements should not be limited by these terms. These terms are only used to distinguish one element from another element. For instance, a first element discussed below could be termed a second element without departing from the scope of the disclosure. Similarly, the second element could also be termed the first element. In the disclosure, the singular expressions are intended to include the plural expressions as well, unless the context clearly indicates otherwise.

It will be further understood that the terms “comprise”, “include”, “have”, etc. used in the disclosure, specify the presence of stated features, integers, steps, operations, elements, components, and/or combinations of them but do not preclude the presence or addition of one or more other features, integers, steps, operations, elements, components, and/or combinations thereof. In addition, when a first part such as a layer, film, region, plate, etc. is on a second part, the first part may be not only “directly on” the second part (e.g., without any intervening parts therebetween), but a third part may intervene between them. Furthermore, in the disclosure, when a first part such as a layer, film, region, plate, etc. is formed on a second part, a direction in which the first part is formed is not limited to an upper direction of the second part, but may include a side or a lower direction of the second part. Similarly, when a first part such as a layer, film, region, plat, etc. is “under” a second part, the first part may be not only “directly under” the second part (e.g., without any intervening parts therebetween), but a third part may intervene between them.

As used herein, the singular forms “a,” “an,” and “the” are intended to include the plural forms as well, unless the context clearly indicates otherwise.

As used herein, the terms “use,” “using,” and “used” may be considered synonymous with the terms “utilize,” “utilizing,” and “utilized,” respectively.

As used herein, expressions such as “at least one of”, “one of”, and “selected from”, when preceding a list of elements, modify the entire list of elements and do not modify the individual elements of the list. For example, “at least one selected from a, b and c”, “at least one of a, b or c”, and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof.

As used herein, the term “and/or” includes any and all combinations of one or more of the associated listed items.

Further, the use of “may” when describing embodiments of the present disclosure refers to “one or more embodiments of the present disclosure”. As used herein, the terms “substantially”, “about”, and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ± 30%, 20%, 10%, 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, For example, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The electronic device and/or any other relevant devices or components according to embodiments of the present invention described herein may be implemented utilizing any suitable hardware, firmware (e.g. an application-specific integrated circuit), software, or a combination of software, firmware, and hardware. For example, the various components of the apparatus may be formed on one integrated circuit (IC) chip or on separate IC chips. Further, the various components of the apparatus may be implemented on a flexible printed circuit film, a tape carrier package (TCP), a printed circuit board (PCB), or formed on one substrate. Further, the various components of the apparatus may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the exemplary embodiments of the present invention.

The disclosure relates to a display device. Hereinafter, a display device according to one or more embodiments will be described with reference to the accompanying drawings.

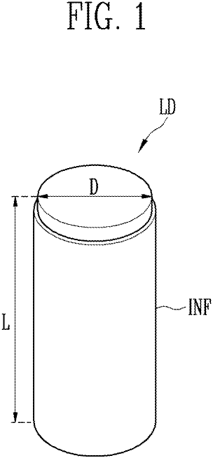

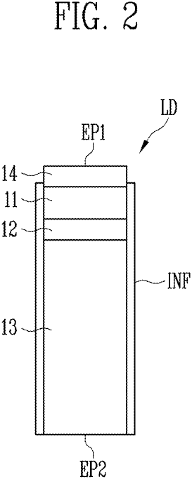

FIG. 1 is a perspective view illustrating a light emitting element according to one or more embodiments. FIG. 2 is a cross-sectional view illustrating the light emitting element according to one or more embodiments. Although a columnar light emitting element LD is shown in FIGS. 1 and 2, the type (or kind) and/or shape of the light emitting element LD is not limited thereto.

Referring to FIGS. 1 and 2, the light emitting element LD may include a first semiconductor layer 11, an active layer 12, and a second semiconductor layer 13. The light emitting element LD may further include an electrode layer 14.

The light emitting element LD may have a columnar shape extending along one direction. The light emitting element LD may have a first end EP1 and a second end EP2. One of the first and second semiconductor layers 11 and 13 may be provided at the first end EP1 of the light emitting element LD. The other of the first and second semiconductor layers 11 and 13 may be provided at the second end EP2 of the light emitting element LD. For example, the first semiconductor layer 11 may be provided adjacent to the first end EP1 of the light emitting element LD, and the second semiconductor layer 13 may be provided adjacent to the second end EP2 of the light emitting element LD.

According to one or more embodiments, the light emitting element LD may be a light emitting element manufactured in a columnar shape through an etching method and/or the like. In the disclosure, the columnar shape may include a rod-like shape and/or a bar-like shape having an aspect ratio greater than 1, such as a cylinder, a polygonal column, and/or the like, and the shape of the cross-section thereof is not particularly limited.

The light emitting element LD may have a size as small as a nano-meter scale to a micro-meter scale. As an example, the light emitting element LD may have a diameter D (or width) and/or a length L ranging from a nano-meter scale to a micro-meter scale. However, the size of the light emitting element LD is not limited thereto. The size of the light emitting element LD may be variously suitably changed according to design conditions of one or more devices using a light emitting device using the light emitting element LD as a light source, for example, a display device.

The first semiconductor layer 11 may be a semiconductor layer of a first conductivity type. For example, the first semiconductor layer 11 may include a P-type semiconductor layer. For example, the first semiconductor layer 11 may include a P-type semiconductor layer including at least one semiconductor material of InAlGaN, GaN, AlGaN, InGaN, or AlN, and doped with a first conductivity type dopant such as Mg and/or the like. However, the material constituting the first semiconductor layer 11 is not limited thereto, and one or more other suitable materials may be used to form the first semiconductor layer 11.

The active layer 12 may be provided between the first semiconductor layer 11 and the second semiconductor layer 13. The active layer 12 may include any one of a single well structure, a multi-well structure, a single quantum well structure, a multi-quantum well (MQW) structure, a quantum dot structure, and a quantum wire structure, but the disclosure is not necessarily limited thereto. The active layer 12 may include GaN, InGaN, InAlGaN, AlGaN, and/or AIN, and one or more other suitable materials may be used to form the active layer 12.

When a voltage equal to or greater than a threshold voltage is applied to both ends of the light emitting element LD, the light emitting element LD may emit light while electron-hole pairs are combined in the active layer 12. By controlling the light emission of the light emitting element LD using this principle, the light emitting element LD may be used as a light source of suitable light emitting devices, including pixels of a display device.

The second semiconductor layer 13 may be provided on the active layer 12 and may include a semiconductor layer of a different type from that of the first semiconductor layer 11. The second semiconductor layer 13 may include an N-type semiconductor layer. For example, the second semiconductor layer 13 may include an N-type semiconductor layer including any one semiconductor material of InAlGaN, GaN, AlGaN, InGaN, or AIN, and doped with a second conductivity type dopant such as Si, Ge, Sn, and/or the like. However, the material constituting the second semiconductor layer 13 is not limited thereto, and one or more other suitable materials may be used to form the second semiconductor layer 13.

The electrode layer 14 may be provided on the first end EP1 and/or the second end EP2 of the light emitting element LD. FIG. 2 shows a case in which the electrode layer 14 is formed on the first semiconductor layer 11, but the disclosure is not necessarily limited thereto. For example, a separate electrode layer may be further provided on the second semiconductor layer 13.

The electrode layer 14 may include a transparent metal and/or a transparent metal oxide. For example, the electrode layer 14 may include at least one of indium tin oxide (ITO), indium zinc oxide (IZO), or zinc tin oxide (ZTO), but the disclosure is not limited thereto. As such, when the electrode layer 14 is formed of a transparent metal and/or a transparent metal oxide, light generated in the active layer 12 of the light emitting element LD may pass through the electrode layer 14 and be emitted to outside of the light emitting element LD.

An insulating film INF may be provided on a surface of the light emitting element LD. The insulating film INF may be directly provided on a surface of the first semiconductor layer 11, the active layer 12, the second semiconductor layer 13, and/or the electrode layer 14. The insulating film INF may expose the first and second ends EP1 and EP2 of the light emitting element LD having different polarities. According to one or more embodiments, the insulating film INF may expose side portions of the electrode layer 14 and/or the second semiconductor layer 13 adjacent to the first and second ends EP1 and EP2 of the light emitting element LD.

The insulating film INF may prevent or reduce the risk of an electrical short circuit that may occur when the active layer 12 comes into contact with a conductive material other than the first and second semiconductor layers 11 and 13. In addition, the insulating film INF may minimize or reduce surface defects of light emitting elements LD, thereby improving lifespan and luminous efficiency of the light emitting elements LD.

The insulating film INF may include at least one of silicon oxide (SiOx), silicon nitride (SiNx), silicon oxynitride (SiOxNy), aluminum nitride (AINx), aluminum oxide (AlOx), zirconium oxide (ZrOx), hafnium oxide (HfOx), or titanium oxide (TiOx). For example, the insulating film INF may be formed of a double layer, and each layer constituting the double layer may include different materials. For example, the insulating film INF may be formed of a double layer including aluminum oxide (AlOx) and silicon oxide (SiOx), but the disclosure is not limited thereto. According to one or more embodiments, the insulating film INF may not be provided.

A light emitting device including the above-described light emitting element LD may be used in one or more suitable types (or kinds) of devices requiring a light source, such as a display device. For example, light emitting elements LD may be provided in each pixel of a display panel, and the light emitting elements LD may be used as light sources of each pixel. However, the field of application of the light emitting element LD is not limited to the above-described example. For example, the light emitting element LD may be used in other types (or kinds) of devices that require a light source, such as a lighting device.

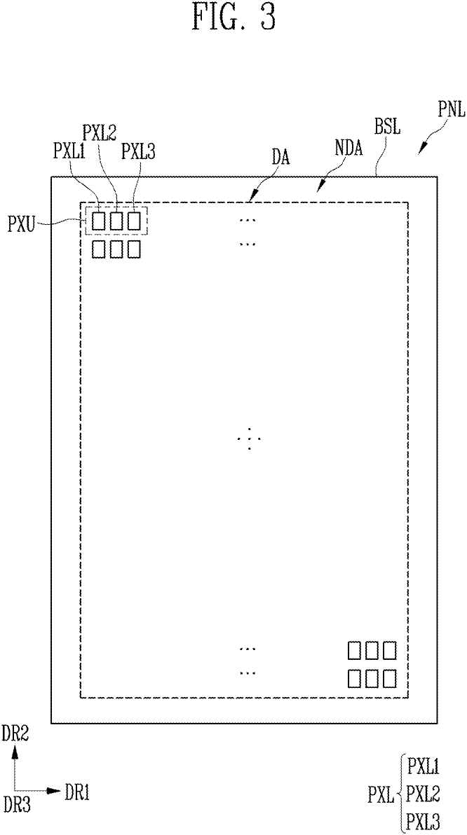

FIG. 3 is a plan view illustrating a display device according to one or more embodiments.

FIG. 3 shows a display device, particularly, a display panel PNL provided in the display device, as an example of an electronic device in which the light emitting element LD described in the embodiments of FIGS. 1 and 2 can be used as a light source.

For convenience of description, FIG. 3 schematically shows a structure of the display panel PNL with a display area DA as the center. However, according to one or more embodiments, at least one driving circuit unit (for example, at least one of a scan driver and a data driver), wirings, and/or pads may be further provided on the display panel PNL.

Referring to FIG. 3, the display panel PNL and a base layer BSL for forming the same may include the display area DA for displaying an image and a non-display area NDA excluding the display area DA. The display area DA may constitute a screen on which an image is displayed, and the non-display area NDA may be an area other than the display area DA.

A pixel unit PXU may be provided in the display area DA. The pixel unit PXU may include a first pixel PXL1, a second pixel PXL2, and/or a third pixel PXL3. Hereinafter, when at least one pixel among the first pixel PXL1, the second pixel PXL2, and the third pixel PXL3 is arbitrarily referred to, or when two or more types (or kinds) of pixels are generically referred to, they will be referred to as “pixel PXL” or “pixels PXL”.

Pixels PXL may be regularly arranged according to a stripe or pentile (PENTILE^{®}) arrangement structure (PENTILE® is a registered trademark owned by Samsung Display Co., Ltd.). However, an arrangement structure of the pixels PXL is not limited thereto, and the pixels PXL may be arranged in the display area DA in one or more suitable structures and/or methods.

According to one or more embodiments, two or more types of pixels PXL emitting light of different colors may be provided in the display area DA. For example, first pixels PXL1 emitting light of a first color, second pixels PXL2 emitting light of a second color, and third pixels PXL3 emitting light of a third color may be arranged in the display area DA. First to third pixels PXL1, PXL2, and PXL3 provided adjacent to each other may constitute one pixel unit PXU capable of emitting light of various colors. For example, each of the first to third pixels PXL1, PXL2, and PXL3 may be a pixel emitting light of a set or predetermined color. According to one or more embodiments, the first pixel PXL1 may be a red pixel emitting red light, the second pixel PXL2 may be a green pixel emitting green light, and the third pixel PXL3 may be a blue pixel emitting blue light, but the disclosure is not limited thereto.

In one or more embodiments, the first pixel PXL1, the second pixel PXL2, and the third pixel PXL3 may include light emitting elements emitting light of the same color, and may include color conversion layers and/or color filter layers of different colors provided on the light emitting elements to emit light of the first color, the second color, and the third color. In one or more other embodiments, the first pixel PXL1, the second pixel PXL2, and the third pixel PXL3 may include a light emitting element of the first color, a light emitting element of the second color, and a light emitting element of the third color as light sources, and may emit light of the first color, the second color, and the third color, respectively. However, the color, type (or kind), and/or number of pixels PXL constituting each pixel unit PXU is not particularly limited. For example, the color of light emitted by each pixel PXL may be variously suitably changed.

The pixel PXL may include at least one light source driven by a set or predetermined control signal (for example, a scan signal and a data signal) and/or a set or predetermined power source (for example, a first power source and a second power source). In one or more embodiments, the light source may include at least one light emitting element LD according to any one of the embodiments of FIGS. 1 and 2, for example, ultra-small columnar light emitting elements LD having a size as small as a nano-meter scale to a micro-meter scale. However, the disclosure is not necessarily limited thereto, and one or more suitable types (or kinds) of light emitting elements LD may be used as the light source of the pixel PXL.

In one or more embodiments, each pixel PXL may be configured as an active type pixel. However, the types (or kinds), structures, and/or driving methods of the pixels PXL applicable to the display device are not particularly limited. For example, each pixel PXL may be configured as a pixel of a passive or active light emitting display device having various suitable structures and/or driving methods.

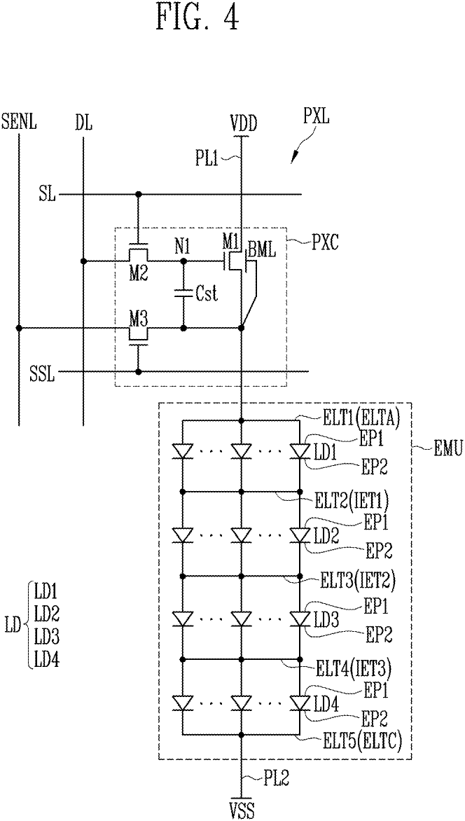

FIG. 4 is a circuit diagram illustrating a pixel according to one or more embodiments.

A pixel PXL shown in FIG. 4 may be any one of the first pixel PXL1, the second pixel PXL2, and the third pixel PXL3 provided in the display panel PNL of FIG. 3. The first pixel PXL1, the second pixel PXL2, and the third pixel PXL3 may have substantially the same or similar structure.

Referring to FIG. 4, the pixel PXL may further include an emission unit EMU for generating light having a luminance corresponding to a data signal and a pixel circuit PXC for driving the emission unit EMU.

The pixel circuit PXC may be connected (e.g., electrically coupled) between a first power source VDD and the emission unit EMU. In addition, the pixel circuit PXC may be connected to a scan line SL and a data line DL of a corresponding pixel PXL to control the operation of the emission unit EMU in response to a scan signal and a data signal supplied from the scan line SL and the data line DL. In one or more embodiments, the pixel circuit PXC may be further selectively connected to a sensing signal line SSL and a sensing line SENL.

The pixel circuit PXC may include at least one transistor and a capacitor. For example, the pixel circuit PXC may include a first transistor M1, a second transistor M2, a third transistor M3, and a storage capacitor Cst.

The first transistor M1 may be connected between the first power source VDD and a first connection electrode ELT1. A gate electrode of the first transistor M1 may be connected to a first node N1. The first transistor M1 may control a driving current supplied to the emission unit EMU in response to a voltage of the first node N1. For example, the first transistor M1 may be a driving transistor that controls the driving current of the pixel PXL.

In one or more embodiments, the first transistor M1 may optionally include a lower conductive layer BML (also referred to as a lower electrode, a back gate electrode, or a lower light blocking layer). The gate electrode of the first transistor M1 and the lower conductive layer BML may overlap each other with an insulating layer interposed therebetween. In one or more embodiments, the lower conductive layer BML may be connected to one electrode of the first transistor M1, for example, a source or drain electrode.

When the first transistor M1 includes the lower conductive layer BML, a back-biasing technique (or a sync technique) for shifting a threshold voltage of the transistor M1 in a negative direction or a positive direction by applying a back-biasing voltage to the lower conductive layer BML of the first transistor M1 when the pixel PXL is driven may be applied. For example, the threshold voltage of the first transistor M1 may be shifted in a negative direction or a positive direction by connecting the lower conductive layer BML to the source electrode of the first transistor M1 and applying a source-sync technique. In addition, when the lower conductive layer BML is provided under a semiconductor pattern constituting a channel of the first transistor M1, operating characteristics of the first transistor M1 may be stabilized because the lower conductive layer BML serves as a light blocking pattern. However, the function and/or utilization method of the lower conductive layer BML is not limited thereto.

The second transistor M2 may be connected between the data line DL and the first node N1. In addition, a gate electrode of the second transistor M2 may be connected to the scan line SL. The second transistor M2 may be turned on when the scan signal of a gate-on voltage (for example, a high level voltage) is supplied from the scan line SL to connect the data line DL and the first node N1.

In each frame period, the data signal of a corresponding frame may be supplied to the data line DL, and the data signal may be transferred to the first node N1 through the second transistor M2 turned on during a period in which the scan signal of the gate-on voltage is supplied. For example, the second transistor M2 may be a switching transistor for transferring each data signal to inside of the pixel PXL.

One electrode of the storage capacitor Cst may be connected to the first node N1, and the other electrode may be connected to a second electrode of the first transistor M1. The storage capacitor Cst may be charged with a voltage corresponding to the data signal supplied to the first node N1 during each frame period.

The third transistor M3 may be connected between the first connection electrode ELT1 (or the second electrode of the first transistor M1) and the sensing line SENL. A gate electrode of the third transistor M3 may be connected to the sensing signal line SSL. The third transistor M3 may transfer a voltage value applied to the first connection electrode ELT1 to the sensing line SENL according to a sensing signal supplied to the sensing signal line SSL. The voltage value transferred through the sensing line SENL may be provided to an external circuit (for example, a timing controller), and the external circuit may extract characteristic information of each pixel PXL (for example, the threshold voltage of the transistor M1 or the like) based on the provided voltage value. The extracted characteristic information may be used to convert image data to compensate for characteristic deviation between the pixels PXL.

Although all of transistors included in the pixel circuit PXC are shown as n-type transistors in FIG. 4, the disclosure is not limited thereto. For example, at least one of the first, second, or third transistors M1, M2, and M3 may be changed to a p-type transistor.

In addition, the structure and driving method of the pixel PXL may be variously suitably changed. For example, the pixel circuit PXC may be composed of pixel circuits having one or more suitable structures and/or driving methods in addition to the embodiment shown in FIG. 4.

For example, the pixel circuit PXC may not include the third transistor M3. In one or more embodiments, the pixel circuit PXC may further include other circuit elements such as a compensation transistor for compensating for the threshold voltage of the first transistor M1, an initialization transistor for initializing a voltage of the first node N1 and/or the first connection electrode ELT1, an emission control transistor for controlling a period in which the driving current is supplied to the emission unit EMU, and/or a boosting capacitor for boosting the voltage of the first node N1.

The emission unit EMU may include at least one light emitting element LD, for example, a plurality of light emitting elements LD connected between the first power source VDD and a second power source VSS.

For example, the emission unit EMU may include the first connection electrode ELT1 connected to the first power source VDD through the pixel circuit PXC and a first power source line PL1, a fifth connection electrode ELT5 connected to the second power source VSS through a second power source line PL2, and a plurality of light emitting elements LD connected between the first and fifth connection electrodes ELT1 and ELT5.

The first power source VDD and the second power source VSS may have different potentials so that the light emitting elements LD emit light. For example, the first power source VDD may be set as a high potential power source, and the second power source VSS may be set as a low potential power source.

In one or more embodiments, the emission unit EMU may include at least one series stage. Each series stage may include a pair of electrodes (for example, two electrodes) and at least one light emitting element LD connected in a forward direction between the pair of electrodes. Here, the number of series stages constituting the emission unit EMU and the number of light emitting elements LD constituting each series stage are not particularly limited. For example, the number of light emitting elements LD constituting each series stage may be the same or different from each other, and the number of light emitting elements LD is not particularly limited.

For example, the emission unit EMU may include a first series stage including at least one first light emitting element LD1, a second series stage including at least one second light emitting element LD2, a third series stage including at least one third light emitting element LD3, and a fourth series stage including at least one fourth light emitting element LD4.

The first series stage may include the first connection electrode ELT1, a second connection electrode ELT2, and at least one first light emitting element LD1 connected between the first and second connection electrodes ELT1 and ELT2. Each first light emitting element LD1 may be connected in a forward direction between the first and second connection electrodes ELT1 and ELT2. For example, a first end EP1 of the first light emitting element LD1 may be connected to the first connection electrode ELT1, and a second end EP2 of the first light emitting element LD1 may be connected to the second connection electrode ELT2.

The second series stage may include the second connection electrode ELT2, a third connection electrode ELT3, and at least one second light emitting element LD2 connected between the second and third connection electrodes ELT2 and ELT3. Each second light emitting element LD2 may be connected in a forward direction between the second and third connection electrodes ELT2 and ELT3. For example, a first end EP1 of the second light emitting element LD2 may be connected tc the second connection electrode ELT2, and a second end EP2 of the second light emitting element LD2 may be connected to the third connection electrode ELT3.

The third series stage may include the third connection electrode ELT3, a fourth connection electrode ELT4, and at least one third light emitting element LD3 connected between the third and fourth connection electrodes ELT3 and ELT4. Each third light emitting element LD3 may be connected in a forward direction between the third and fourth connection electrodes ELT3 and ELT4. For example, a first end EP1 of the third light emitting element LD3 may be connected to the third connection electrode ELT3, and a second end EP2 of the third light emitting element LD3 may be connected to the fourth connection electrode ELT4.

The fourth series stage may include the fourth connection electrode ELT4, the fifth connection electrode ELT5, and at least one fourth light emitting element LD4 connected between the fourth and fifth connection electrodes ELT4 and ELT5. Each fourth light emitting element LD4 may be connected in a forward direction between the fourth and fifth connection electrodes ELT4 and ELT5. For example, a first end EP1 of the fourth light emitting element LD4 may be connected to the fourth connection electrode ELT4, and a second end EP2 of the fourth light emitting element LD4 may be connected to the fifth connection electrode ELT5.

A first electrode of the emission unit EMU, for example, the first connection electrode ELT1 may be an anode connection electrode ELTA of the emission unit EMU. The last electrode of the emission unit EMU, for example, the fifth connection electrode ELT5 may be a cathode connection electrode ELTC of the emission unit EMU. For example, the light emitting elements LD may be electrically connected between the anode connection electrode ELTA and the cathode connection electrode ELTC.

The remaining electrodes of the emission unit EMU, for example, the second connection electrode ELT2, the third connection electrode ELT3, and/or the fourth connection electrode ELT4 may constitute intermediate electrodes. For example, the second connection electrode ELT2 may constitute a first intermediate electrode IET1, the third connection electrode ELT3 may constitute a second intermediate electrode IET2, and the fourth connection electrode ELT4 may constitute a third intermediate electrode IET3.

When the light emitting elements LD are connected in a series/parallel structure (e.g., a structure including connection(s) in series and connection(s) in parallel), power efficiency may be improved compared to a case where the same number of light emitting elements LD are connected only in parallel. In addition, in a pixel PXL in which light emitting elements LD are connected in a series/parallel structure, even if a short defect (e.g., a short circuit) occurs in some series stages, a set or predetermined luminance may be expressed through the light emitting elements LD of the remaining series stages, so that the possibility of dark spot defects in the pixel PXL may be reduced. However, the disclosure is not necessarily limited thereto, and the emission unit EMU may be configured by connecting the light emitting elements LD only in series, or the emission unit EMU may be configured by connecting the light emitting elements LD only in parallel.

Each of the light emitting elements LD may include a first end EP1 (for example, a p-type end) connected to the first power source VDD via at least one electrode (for example, the first connection electrode ELT1), the pixel circuit PXC, and/or the first power source line PL1, and a second end EP2 (for example, an n-type end) connected to the second power source VSS via at least one other electrode (for example, the fifth connection electrode ELT5) and/or the second power source line PL2. For example, the light emitting elements LD may be connected in a forward direction between the first power source VDD and the second power source VSS. The light emitting elements LD connected in the forward direction may constitute effective (or suitable) light sources of the emission unit EMU.

When the driving current is supplied through a corresponding pixel circuit PXC, the light emitting elements LD may emit light with a luminance corresponding to the driving current. For example, during each frame period, the pixel circuit PXC may supply the driving current corresponding to a grayscale value to be expressed in a corresponding frame to the emission unit EMU. Accordingly, while the light emitting elements LD emit light with a luminance corresponding to the driving current, the emission unit EMU may express the luminance corresponding to the driving current.

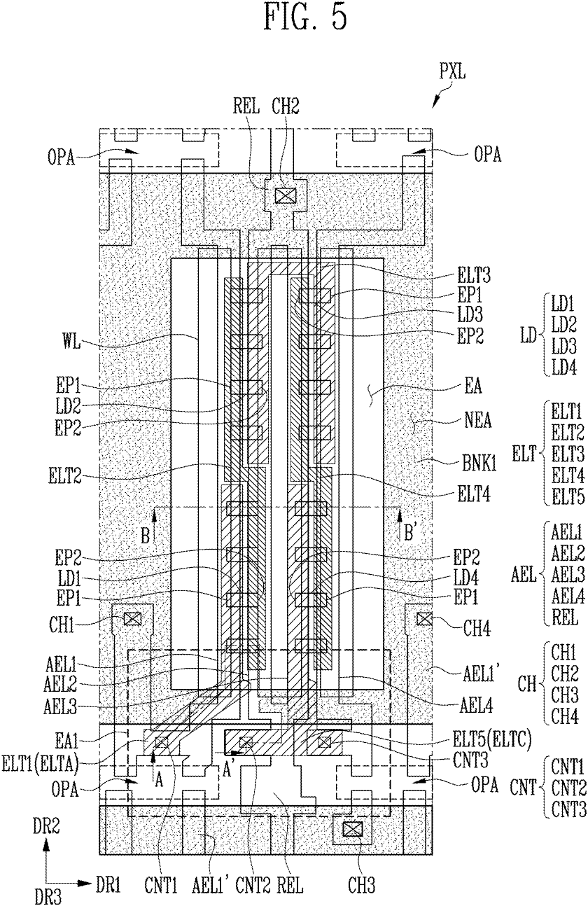

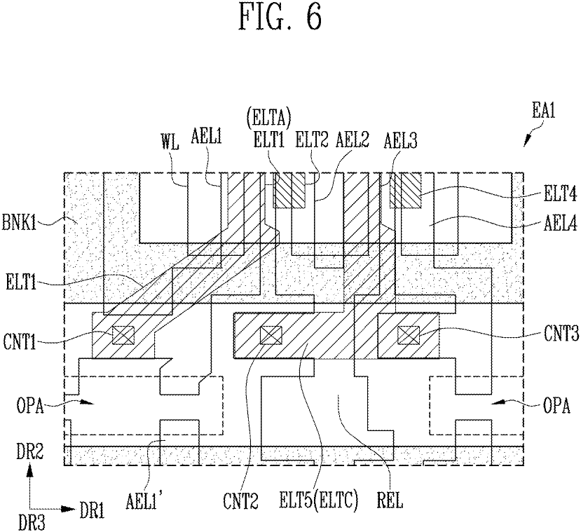

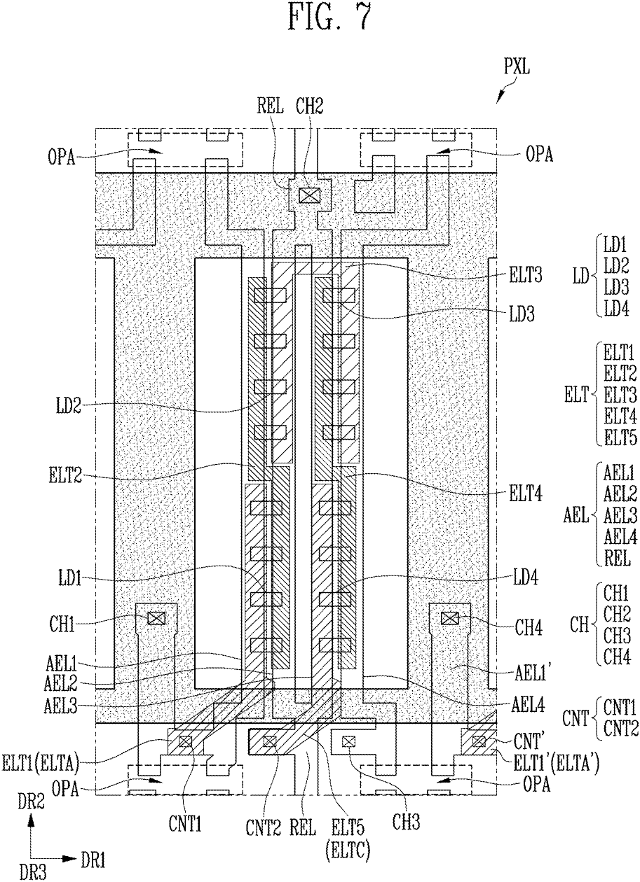

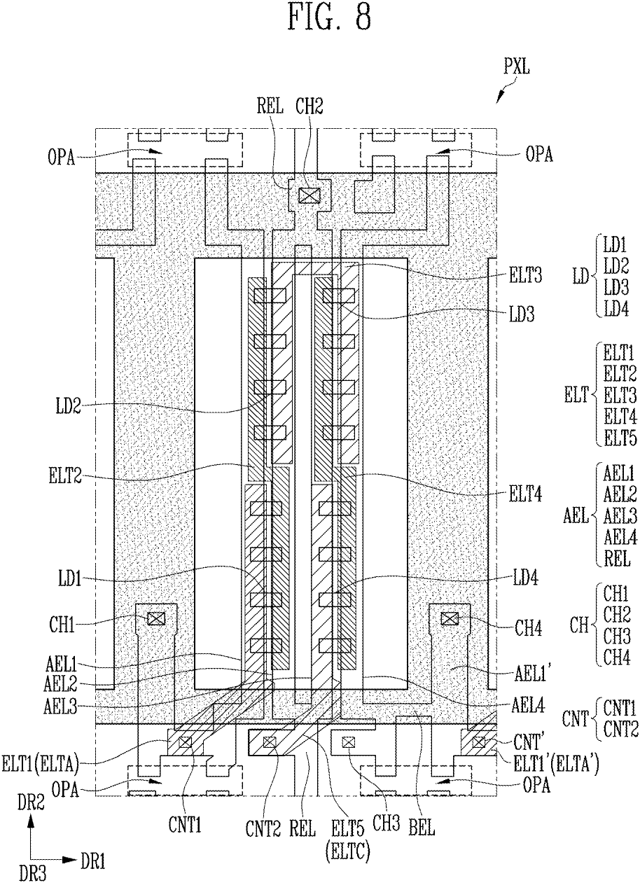

FIGS. 5 to 8 are plan views illustrating pixels according to embodiments. FIG. 6 may be an enlarged view of the area EA1 shown in FIG. 5. FIGS. 5 and 6 may be diagrams schematically illustrating a pixel PXL according to a first embodiment. FIG. 7 may be a diagram schematically illustrating a pixel PXL according to a second embodiment. FIG. 8 may be a diagram schematically illustrating a pixel PXL according to a third embodiment.

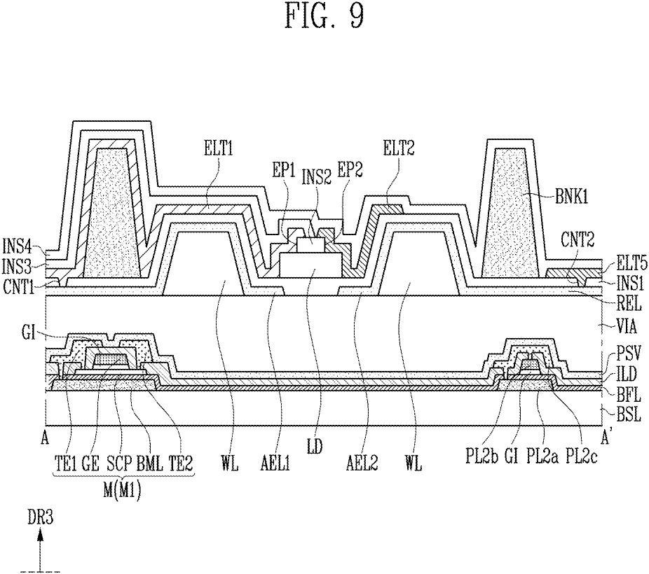

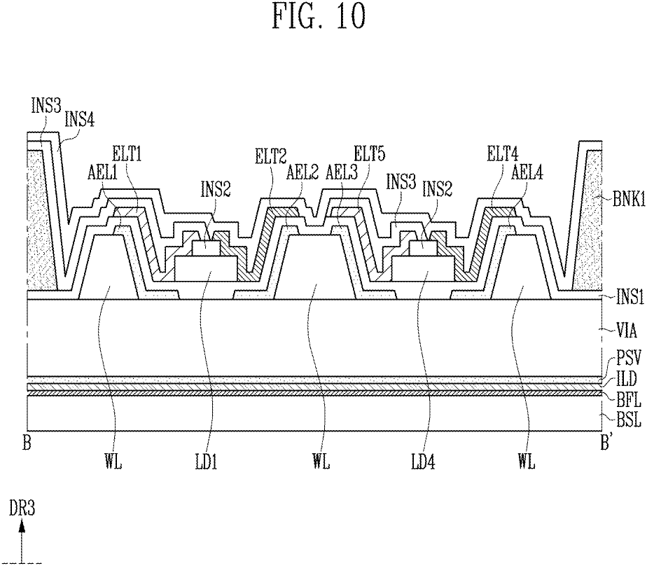

FIG. 9 is a schematic cross-sectional view taken along the line A-A′ of FIG. 5. FIG. 10 is a schematic cross-sectional view taken along the line B—B′ of FIG. 5.

For example, FIGS. 5 to 10 may illustrate any one of the first to third pixels PXL1, PXL2, and PXL3 constituting the pixel unit PXU, and the first to third pixels PXL1, PXL2, and PXL3 may have substantially the same or similar structures.

In addition, FIGS. 5, 7, and 8 show one or more embodiments in which each pixel PXL includes light emitting elements LD provided in four serial stages as shown in FIG. 4, but the number of serial stages of each pixel PXL may be variously suitably changed according to embodiments.

Hereinafter, when one or more light emitting elements among the first to fourth light emitting elements LD1, LD2, LD3, and LD4 are arbitrarily referred to, or two or more types (or kinds) of light emitting elements are generically referred to, they will be referred to as “light emitting element LD” or “light emitting elements LD”.

In addition, when at least one alignment electrode among alignment electrodes including the first to fourth alignment electrodes AEL1, AEL2, AEL3, and AEL4 is arbitrarily referred to, it may be referred to as “alignment electrode AEL” or “alignment electrodes AEL”, and when at least one electrode among electrodes including the first to fifth connection electrodes ELT1, ELT2, ELT3, ELT4, and ELT5 is arbitrarily referred to, it may be referred to as “connection electrode ELT” or “connection electrodes ELT”.

First, the pixel PXL according to the first embodiment will be described with reference to FIGS. 5 and 6.

Referring to FIG. 5, the pixel PXL may include an emission area EA and a non-emission area NEA. The emission area EA may be an area including light emitting elements LD and capable of emitting light. The non-emission area NEA may be provided to surround the emission area EA. The non-emission area NEA may be an area in which a first bank BNK1 surrounding (e.g., around) the emission area EA is provided. The first bank BNK1 may be provided in the non-emission area NEA to at least partially surround the emission area EA.

An opening overlapping the emission area EA may be formed in the first bank BNK1. The opening of the first bank BNK1 may provide a space in which light emitting elements LD may be provided in a step (or act) of supplying the light emitting elements LD to each of the pixels PXL. For example, a desired type (or kind) and/or amount of light emitting element ink may be supplied to the space partitioned by the opening of the first bank BNK1. Here, the light emitting element ink may include the light emitting elements LD and a solvent.

The first bank BNK1 may include an organic material such as an acrylate resin, an epoxy resin, a phenolic resin, a polyamide resin, a polyimide resin, a polyester resin, a polyphenylenesulfide resin, and/or benzocyclobutene (BCB). However, the disclosure is not necessarily limited thereto, and the first bank BNK1 may include one or more suitable inorganic materials such as silicon oxide (SiOx), silicon nitride (SiNx), silicon oxynitride (SiOxNy), aluminum nitride (AINx), aluminum oxide (AlOx), zirconium oxide (ZrOx), hafnium oxide (HfOx), and/or titanium oxide (TiOx).

According to one or more embodiments, the first bank BNK1 may include at least one light blocking and/or reflective material. Accordingly, light leakage between adjacent pixels PXL may be prevented or reduced. For example, the first bank BNK1 may include a black pigment, but the disclosure is not limited thereto.

The pixel PXL may include partition walls WL, alignment electrodes AEL, light emitting elements LD, and connection electrodes ELT.

The partition walls WL may be provided in at least the emission area EA. The partition walls WL may be at least partially provided in the non-emission area NEA. The partition walls WL may extend along a second direction DR2 and may be spaced apart from each other along a first direction DR1.

Each of the partition walls WL may partially overlap the at least one alignment electrode AEL in at least the emission area EA. For example, the partition walls WL may be provided under the alignment electrodes AEL. As the partition walls WL are provided under the alignment electrodes AEL, the alignment electrodes AEL may protrude in an upper direction of the pixel PXL, for example, a third direction DR3 in an area in which the partition walls WL are formed. When the partition walls WL and/or the alignment electrodes AEL include a reflective material, a reflective wall structure may be formed around the light emitting elements LD. Accordingly, light emitted from the light emitting elements LD may be emitted toward the top of the pixel PXL (for example, a front direction of the display panel PNL including a set or predetermined viewing angle range), so that light output efficiency of the display panel PNL may be improved.

The alignment electrodes AEL may be provided on a base layer BSL (refer to FIG. 9). The alignment electrodes AEL may be provided in the emission area EA. The alignment electrodes AEL may extend in the second direction DR2. The alignment electrodes AEL may be spaced apart from each other along the first direction DR1. For example, the alignment electrodes AEL may include a first alignment electrode AEL1, a second alignment electrode AEL2, a third alignment electrode AEL3, and a fourth alignment electrode AEL4 sequentially arranged along the first direction DR1. According to one or more embodiments, the alignment electrodes AEL may further include a root alignment electrode REL.

The alignment electrodes AEL may receive different electrical signals in a step (or act) of aligning the light emitting elements LD. For example, the first alignment electrode AEL1 may receive a first alignment signal, and the second alignment electrode AEL2 may receive a second alignment signal. The third alignment electrode AEL3 may receive the second alignment signal, and the fourth alignment electrode AEL4 may receive the first alignment signal.

According to one or more embodiments, the first alignment signal and the second alignment signal may have different waveforms, potentials, and/or phases. Accordingly, in order to align the light emitting elements LD, an electric field may be formed between the first alignment electrode AEL1 and the second alignment electrode AEL2, and the light emitting elements LD may be aligned between the first alignment electrode AEL1 and the second alignment electrode AEL2. In addition, in order to align the light emitting elements LD, an electric field may be formed between the third alignment electrode AEL3 and the fourth alignment electrode AEL4, and the light emitting elements LD may be aligned between the third alignment electrode AEL3 and the fourth alignment electrode AEL4. According to one or more embodiments, the first alignment signal may be an AC voltage, and the second alignment signal may be a ground voltage. However, the disclosure is not limited to the above-described examples.

According to one or more embodiments, the alignment electrodes AEL may be electrically connected to other wirings through contact holes CH. The contact holes CH may include first to fourth contact holes CH1 to CH4. For example, the first alignment electrode AEL1 may be electrically connected to the first power source line PL1 supplying the first power source VDD through the first contact hole CH1. The root alignment electrode REL may be electrically connected to the second power source line PL2 supplying the second power source VSS through the second contact hole CH2. In one or more embodiments, a portion of the alignment electrode AEL separated from the fourth alignment electrode AEL4 by an open area OPA may be electrically connected to another wiring through the third contact hole CH3. A first alignment electrode AEL1′, which is another portion of the alignment electrode AEL, may be electrically connected to another wiring through the fourth contact hole CH4.

According to one or more embodiments, the root alignment electrode REL may be integrally formed with the second alignment electrode AEL2 and the third alignment electrode AEL3 (refer to FIG. 6). The root alignment electrode REL may be physically connected to the second alignment electrode AEL2 and the third alignment electrode AEL3. In this case, because the second alignment electrode AEL2 and the third alignment electrode AEL3 are integrally formed and are physically connected to an adjacent root alignment electrode REL (e.g., the second alignment electrode AEL2 and the third alignment electrode AEL3 of adjacent pixels PXL are connected to each other), the resistance of electrodes including the second alignment electrode AEL2 and the third alignment electrode AEL3 may be reduced.

According to one or more embodiments, in order to individually drive the first to third pixels PXL1, PXL2, and PXL3, portions of the alignment electrodes AEL may be cut. Portions of the alignment electrodes AEL may be removed by etching the portions of the alignment electrodes AEL, and open areas OPA may be formed. Accordingly, the first alignment electrode AEL1 of one pixel PXL and the first alignment electrode AEL1′ of an adjacent pixel PXL may be separated by an open area OPA. In addition, the fourth alignment electrode AEL4 of one pixel PXL may be separated from another electrode of an adjacent pixel PXL by an open area OPA. As described above, when an etching process for forming the open area OPA is performed, the second alignment electrode AEL2 and the third alignment electrode AEL3 may not be cut.

According to one or more embodiments, the alignment electrodes AEL may be electrically connected to at least one of the anode connection electrode ELTA and the cathode connection electrode ELTC. For example, the first alignment electrode AEL1 may be electrically connected to the first connection electrode ELT1 through a first contact portion CNT1. The second and third alignment electrodes AEL2 and AEL3 may be electrically connected to the fifth connection electrode ELT5 through the root alignment electrode REL and a second contact portion CNT2. The fourth alignment electrode AEL4 may be electrically connected to the fifth connection electrode ELT5 through a third contact portion CNT3.

The light emitting elements LD may be provided on the alignment electrodes AEL. Each of the light emitting elements LD may be aligned between the alignment electrodes AEL in the emission area EA.

The light emitting elements LD may be electrically connected to the connection electrodes ELT. Each of the light emitting elements LD may be electrically connected between a pair of connection electrodes ELT.

Each of the light emitting elements LD may be aligned between a pair of alignment electrodes AEL in the emission area EA. Also, each of the light emitting elements LD may be electrically connected between a pair of connection electrodes ELT. For example, as described above, the light emitting elements LD may be electrically connected between the anode connection electrode ELTA (the first connection electrode ELT1 of the present embodiment) and the cathode connection electrode ELTC (the fifth connection electrode ELT5 of the present embodiment).

The first light emitting element LD1 may be aligned between the first and second alignment electrodes AEL1 and AEL2. The first light emitting element LD1 may be electrically connected between the first and second connection electrodes ELT1 and ELT2. For example, the first light emitting element LD1 may be aligned in a first area (for example, a lower area) of the first and second alignment electrodes AEL1 and AEL2, the first end EP1 of the first light emitting element LD1 may be electrically connected to the first connection electrode ELT1, and a second end EP2 of the first light emitting element LD1 may be electrically connected to the second connection electrode ELT2.

The second light emitting element LD2 may be aligned between the first and second alignment electrodes AEL1 and AEL2. The second light emitting element LD2 may be electrically connected between the second and third connection electrodes ELT2 and ELT3. For example, the second light emitting element LD2 may be aligned in a second area (for example, an upper area) of the first and second alignment electrodes AEL1 and AEL2, the first end EP1 of the second light emitting element LD2 may be electrically connected to the second connection electrode ELT2, and the second end EP2 of the second light emitting element LD2 may be electrically connected to the third connection electrode ELT3.

The third light emitting element LD3 may be aligned between the third and fourth alignment electrodes AEL3 and AEL4. The third light emitting element LD3 may be electrically connected between the third and fourth connection electrodes ELT3 and ELT4. For example, the third light emitting element LD3 may be aligned in a first area (for example, an upper area) of the third and fourth alignment electrodes AEL3 and AEL4, the first end EP1 of the third light emitting element LD3 may be electrically connected to the third connection electrode ELT3, and a second end EP2 of the third light emitting element LD3 may be electrically connected to the fourth connection electrode ELT4.

The fourth light emitting element LD4 may be aligned between the third and fourth alignment electrodes AEL3 and AEL4. The fourth light emitting element LD4 may be electrically connected between the fourth and fifth connection electrodes ELT4 and ELT5. For example, the fourth light emitting element LD4 may be aligned in a second area (for example, a lower area) of the third and fourth alignment electrodes AEL3 and AEL4, the first end EP1 of the fourth light emitting element LD4 may be electrically connected to the fourth connection electrode ELT4, and a second end EP2 of the fourth light emitting element LD4 may be electrically connected to the fifth connection electrode ELT5.

For example, the first light emitting element LD1 may be positioned in a lower left area of the emission area EA, and the second light emitting element LD2 may be positioned in an upper left area of the emission area EA. The third light emitting element LD3 may be positioned in an upper right area of the emission area EA, and the fourth light emitting element LD4 may be positioned in a lower right area of the emission area EA. However, the arrangement and/or connection structure of the light emitting elements LD may be variously suitably changed according to the structure of the emission unit EMU and/or the number of series stages.

Each of the connection electrodes ELT may be provided in at least the emission area EA, and may be provided to overlap the at least one alignment electrode AEL and/or the light emitting element LD. For example, the connection electrodes ELT may be formed on the light emitting elements LD to overlap the light emitting elements LD, and may be electrically connected to the light emitting elements LD.

According to one or more embodiments, the connection electrodes ELT may be electrically connected to some of the alignment electrodes AEL through contact portions CNT.

The first connection electrode ELT1 may be provided on first ends EP1 of the first light emitting elements LD1 to be electrically connected to the first ends EP1 of the first light emitting elements LD1.

The second connection electrode ELT2 may be provided on second ends EP2 of the first light emitting elements LD1 to be electrically connected to the second ends EP2 of the first light emitting elements LD1. Also, the second connection electrode ELT2 may be provided on first ends EP1 of the second light emitting elements LD2 to be electrically connected to the first ends EP1 of the second light emitting elements LD2. For example, the second connection electrode ELT2 may electrically connect the second ends EP2 of the first light emitting elements LD1 and the first ends EP1 of the second light emitting elements LD2 in the emission area EA. To this end, the second connection electrode ELT2 may have a curved shape. For example, the second connection electrode ELT2 may have a bent or curved structure at a boundary between an area in which at least one first light emitting element LD1 is arranged and an area in which at least one second light emitting element LD2 is arranged.

The third connection electrode ELT3 may be provided on second ends EP2 of the second light emitting elements LD2 to be electrically connected to the second ends EP2 of the second light emitting elements LD2. Also, the third connection electrode ELT3 may be provided on first ends EP1 of the third light emitting elements LD3 to be electrically connected to the first ends EP1 of the third light emitting elements LD3. For example, the third connection electrode ELT3 may electrically connect the second ends EP2 of the second light emitting elements LD2 and the first ends EP1 of the third light emitting elements LD3 in the emission area EA. To this end, the third connection electrode ELT3 may have a curved shape. For example, the third connection electrode ELT3 may have a bent or curved structure at a boundary between an area in which at least one second light emitting element LD2 is arranged and an area in which at least one third light emitting element LD3 is arranged.

The fourth connection electrode ELT4 may be provided on second ends EP2 of the third light emitting elements LD3 to be electrically connected to the second ends EP2 of the third light emitting elements LD3. Also, the fourth connection electrode ELT4 may be provided on first ends EP1 of the fourth light emitting elements LD4 to be electrically connected to the first ends EP1 of the fourth light emitting elements LD4. For example, the fourth connection electrode ELT4 may electrically connect the second ends EP2 of the third light emitting elements LD3 and the first ends EP1 of the fourth light emitting elements LD4 in the emission area EA. To this end, the fourth connection electrode ELT4 may have a curved shape. For example, the fourth connection electrode ELT4 may have a bent or curved structure at a boundary between an area in which at least one third light emitting element LD3 is arranged and an area in which at least one fourth light emitting element LD4 is arranged.

The fifth connection electrode ELT5 may be provided on second ends EP2 of the fourth light emitting elements LD4 to be electrically connected to the second ends EP2 of the fourth light emitting elements LD4.

According to one or more embodiments, the anode connection electrode ELTA and the cathode connection electrode ELTC may be formed of the same conductive layer. For example, the anode connection electrode ELTA (for example, the first connection electrode ELT1) and the cathode connection electrode ELTC (for example, the fifth connection electrode ELT5) may include the same conductive layer (e.g., may be on the same level and/or may include the same conductive material). The anode connection electrode ELTA and the cathode connection electrode ELTC may be formed (or patterned) in the same process.

The first connection electrode ELT1, the third connection electrode ELT3, and/or the fifth connection electrode ELT5 may be formed of the same conductive layer (e.g., may be on the same level and/or may include the same conductive material). Also, the second connection electrode ELT2 and the fourth connection electrode ELT4 may be formed of the same conductive layer. However, the disclosure is not necessarily limited to the above-described example. For example, according to one or more embodiments, the first to fifth connection electrodes ELT1, ELT2, ELT3, ELT4, and ELT5 may be formed of the same conductive layer.

According to one or more embodiments, the light emitting elements LD may be connected in a desired shape using the connection electrodes ELT. For example, the first light emitting elements LD1, the second light emitting elements LD2, the third light emitting elements LD3, and the fourth light emitting elements LD4 may be sequentially connected in series using the connection electrodes ELT.

According to one or more embodiments, a portion of the cathode connection electrode ELTC (for example, the fifth connection electrode ELT5) may be electrically connected to the root alignment electrode REL. According to one or more embodiments, another portion of the cathode connection electrode ELTC may be electrically connected to the fourth alignment electrode AEL4. Accordingly, the second to fourth alignment electrodes AEL2 to AEL4 may be electrically connected to each other.

According to one or more embodiments, the number of contact portions CNT provided in one pixel PXL may be plural. For example, according to one or more embodiments, one pixel PXL may include three contact portions CNT. For example, the contact portions CNT may include the first contact portion CNT1, the second contact portion CNT2, and the third contact portion CNT3.

According to one or more embodiments, the number of contact portions CNT defined in each pixel PXL (for example, defined in one sub-pixel) may be less than the number of alignment electrodes AEL. For example, referring to FIG. 5, the number of the contact portions CNT defined in each pixel PXL may be three, and the number of the alignment electrodes AEL may be four.

The first contact portion CNT1 may refer to a portion where the anode connection electrode ELTA (for example, the first connection electrode ELT1) and the first alignment electrode AEL1 are connected.

The second contact portion CNT2 may refer to a portion where the cathode connection electrode ELTC (for example, the fifth connection electrode ELT5) and the root alignment electrode REL are connected. Accordingly, the second and third alignment electrodes AEL2 and AEL3 may be electrically connected to the fifth connection electrode ELT5 through the root alignment electrode REL and the second contact portion CNT2.

The third contact portion CNT3 may refer to a portion where the cathode connection electrode ELTC (for example, the fifth connection electrode ELT5) and the fourth alignment electrode AEL4 are connected.

According to one or more embodiments, the first contact portion CNT1, the second contact portion CNT2, and the third contact portion CNT3 may be arranged in parallel. For example, the first contact portion CNT1, the second contact portion CNT2, and the third contact portion CNT3 may be arranged along a direction adjacent to the first to fourth alignment electrodes AEL1 to AEL4. However, the disclosure is not necessarily limited to the above-described example.

According to one or more embodiments, the fifth connection electrode ELT5 may be connected to the root alignment electrode REL and the fourth alignment electrode AEL4 through the second contact portion CNT2 and the third contact portion CNT3, respectively. For example, the fifth connection electrode ELT5 may overlap the second contact portion CNT2 and the third contact portion CNT3 in a plan view. In this case, the second to fourth alignment electrodes AEL2 to AEL4 may be connected to the fifth connection electrode ELT5. Accordingly, when the light emitting elements LD emit light, the same electrical signal (for example, a cathode signal) may be provided tc the second to fourth alignment electrodes AEL2 to AEL4.

In one or more embodiments, the first connection electrode ELT1 and the fifth connection electrode ELT5 connected to the first contact portion CNT1 may be formed (or patterned) in the same process. For example, the first to third contact portions CNT1 to CNT3 may be provided when the first connection electrode ELT1 and the fifth connection electrode ELT5 are patterned. For example, the contact portions CNT may be formed in the same process, and thus a manufacturing process may be simplified.

According to one or more embodiments, an anode signal provided through the first contact portion CNT1 may be supplied to the light emitting elements LD through the first connection electrode ELT1. For example, the supplied anode signal may be sequentially provided to the first to fourth light emitting elements LD1, LD2, LD3, and LD4.

According to one or more embodiments, a cathode signal provided through the second contact portion CNT2 or the third contact portion CNT3 may be supplied to the light emitting elements LD through the fifth connection electrode ELT5.

For example, the first to fourth light emitting elements LD1 to LD4 may be electrically connected to each other in series, the anode signal may be supplied to the first end EP1 of the first light emitting element LD1 through the first connection electrode ELT1, and the cathode signal may be supplied to the second end EP2 of the fourth light emitting element LD4 through the fifth connection electrode ELT5. Accordingly, the light emitting elements LD may emit light based on the provided electrical signals.

According to one or more embodiments, when the light emitting element LD emits light, the alignment electrodes AEL may not be in a floating state.

For example, because the first connection electrode ELT1 receives the anode signal through the first contact portion CNT1, the anode signal may flow through the first alignment electrode AEL1 connected to the first contact portion CNT1. Because the fifth connection electrode ELT5 receives the cathode signal through the second contact portion CNT2 and/or the third contact portion CNT3, the cathode signal may flow through the second and third alignment electrodes AEL2 and AEL3 integrally formed with the root alignment electrode REL connected to the second contact portion CNT2, and the cathode signal may flow through the fourth alignment electrode AEL4 connected to the third contact portion CNT3.

Accordingly, when the light emitting elements LD emit light, the first alignment electrode AEL1 may be in a state in which the anode signal is provided, and the second to fourth alignment electrodes AEL2 to AEL4 may be in a state in which the cathode signal is provided.

When the light emitting element LD emits light, and when adjacent electrodes are in a floating state, noise may be generated in an electrical signal for light emitting of the light emitting element LD. However, according to one or more embodiments, the fifth connection electrode ELT5 may be commonly connected to the second contact portion CNT2 and the third contact portion CNT3. Accordingly, the electrical signal (for example, the cathode signal for emitting light) may flow through the second to fourth alignment electrodes AEL2 to AEL4. Accordingly, the alignment electrodes AEL may not be in a floating state. As a result, noise for the electrical signal provided to the light emitting element LD may be substantially reduced.

Next, the pixel PXL according to the second embodiment will be described with reference to FIG. 7. Contents that may overlap with those described above will be briefly described or will not be provided again.

Referring to FIG. 7, the pixel PXL according to the second embodiment may be different from the pixel PXL according to the first embodiment in that the third contact portion CNT3 is not included.

According to one or more embodiments, the fifth connection electrode ELT5 may not be connected to the fourth alignment electrode AEL4 by a contact portion. In this case, the fifth connection electrode ELT5 may be connected to the root alignment electrode REL through the second contact portion CNT2 without being connected to the fourth alignment electrode AEL4. For example, the fifth connection electrode ELT5 may be electrically separated from (e.g., not electrically connected to, or electrically insulated from) the fourth alignment electrode AEL4.

According to one or more embodiments, the fourth alignment electrode AEL4 may be electrically connected to the first connection electrode ELT1′ (e.g., anode connection electrode ELTA′) of adjacent pixel PXL through the contact portion CNT′.

According to the present embodiment, the pixel PXL may include only two contact portions including the first contact portion CNT1 for the first connection electrode ELT1 and the second contact portion CNT2 for the fifth connection electrode ELT5. In this case, the number of required contact portions may be reduced, thereby simplifying the manufacturing process.

Next, the pixel PXL according to the third embodiment will be described with reference to FIG. 8. Contents that may overlap with those described above will be briefly described or will not be provided again.

Referring to FIG. 8, the pixel PXL according to the third embodiment may be different from the pixel PXL according to the second embodiment in that a bridge alignment electrode BEL is further included.

According to one or more embodiments, the fourth alignment electrode AEL4 may be connected to a first alignment electrode AEL1′ (for example, may be referred to as an adjacent alignment electrode) of another adjacent pixel PXL by the bridge alignment electrode BEL. For example, when a process for forming the open area OPA is performed, the fourth alignment electrode AEL4 of one pixel PXL and the first alignment electrode AEL1′ of another adjacent pixel PXL may not be separated from each other.

In this case, when the light emitting elements LD emit light, the anode signal supplied to the first alignment electrode AEL1′ of another adjacent pixel PXL may flow through the fourth alignment electrode AEL4. According to the present embodiment, compared to the first embodiment, the number of contact portions CNT may be reduced, and further, the fourth alignment electrode AEL4 may not be in a floating state. As a result, the manufacturing process may be simplified, and noise for the signal provided to the light emitting element LD may also be substantially reduced.

Hereinafter, a cross-sectional structure of the pixel PXL will be described in more detail with reference to FIGS. 9 and 10. FIG. 9 shows the first transistor M1 among various circuit elements constituting the pixel circuit PXC (refer to FIG. 4). When there is no need to separately describe the first to third transistors M1, M2, and M3, they will be generally referred to as “transistor M”. Meanwhile, the structure and/or the position of each layer of the transistors M is not limited to the embodiment shown in FIG. 9, and may be variously suitably changed according to embodiments. For convenience of description, pixel elements and wirings are not shown in FIG. 10.

Pixels PXL according to one or more embodiments may include circuit elements including transistors M provided on a base layer BSL and one or more wirings connected thereto. Elements constituting the above-described emission unit EMU may be provided on the circuit elements.

The base layer BSL may constitute a base member and may be a rigid or flexible substrate or film. For example, the base layer BSL may be a rigid substrate made of glass or tempered glass, a flexible substrate (or thin film) made of plastic and/or metal, or at least one insulating layer. The material and/or properties of the base layer BSL are not particularly limited. In one or more embodiments, the base layer BSL may be substantially transparent. Here, the term “substantially transparent” may mean that light can be transmitted with a set or predetermined transmittance or higher. In another embodiment, the base layer BSL may be translucent or opaque. Also, the base layer BSL may include a reflective material according to one or more embodiments.

A lower conductive layer BML and a first power source conductive layer PL2a may be provided on the base layer BSL. The lower conductive layer BML and the first power source conductive layer PL2a may be provided on the same layer (e.g., on the same level). For example, the lower conductive layer BML and the first power source conductive layer PL2a may be simultaneously (or concurrently) formed in the same process, but the disclosure is not limited thereto. The first power source conductive layer PL2a may constitute the second power source line PL2 described with reference to FIG. 4 or the like.

The lower conductive layer BML and the first power source conductive layer PL2a may be formed of a single layer or a multilayer made of molybdenum (Mo), copper (Cu), aluminum (Al), chromium (Cr), gold (Au), titanium (Ti), nickel (Ni), neodymium (Nd), indium (In), tin (Sn), and/or oxides and/or alloys thereof.

A buffer layer BFL may be provided on the lower conductive layer BML and the first power source conductive layer PL2a. The buffer layer BFL may prevent or reduce the diffusion of impurities into the circuit elements. The buffer layer BFL may be formed of a single layer, but may also be formed of a two or more multilayers. When the buffer layer BFL is formed of a multilayer, each layer may be formed of the same material or may be formed of different materials.

A semiconductor pattern SCP may be provided on the buffer layer BFL. For example, the semiconductor pattern SCP may include a first region in contact with a first transistor electrode TE1, a second region in contact with a second transistor electrode TE2, and a channel region positioned between the first and second regions. According to one or more embodiments, one of the first and second regions may be a source region and the other may be a drain region.

According to one or more embodiments, the semiconductor pattern SCP may be made of polysilicon, amorphous silicon, oxide semiconductor, and/or the like. In one or more embodiments, the channel region of the semiconductor pattern SCP may be an intrinsic semiconductor as a semiconductor pattern not doped with impurities, and the first and second regions of the semiconductor pattern SCP may be semiconductors doped with a set or predetermined impurity.

A gate insulating layer GI may be provided on the buffer layer BFL and the semiconductor pattern SCP. For example, the gate insulating layer Gl may be provided between the semiconductor pattern SCP and a gate electrode GE. Also, the gate insulating layer GI may be provided between the buffer layer BFL and a second power source conductive layer PL2b. The gate insulating layer GI may be formed of a single layer or a multilayer, and may include one or more suitable inorganic materials such as silicon oxide (SiOx), silicon nitride (SiNx), silicon oxynitride (SiOxNy), aluminum nitride (AINx), aluminum oxide (AlOx), zirconium oxide (ZrOx), hafnium oxide (HfOx), and/or titanium oxide (TiOx).

The gate electrode GE of a transistor M and the second power source conductive layer PL2b may be provided on the gate insulating layer Gl. The gate electrode GE and the second power source conductive layer PL2b may be provided on the same layer (e.g., on the same level). For example, the gate electrode GE and the second power source conductive layer PL2b may be simultaneously (or concurrently) formed in the same process, but the disclosure is not limited thereto. The gate electrode GE may be provided on the gate insulating layer Gl to overlap the semiconductor pattern SCP in the third direction DR3. The second power source conductive layer PL2b may be provided on the gate insulating layer Gl to overlap the first power source conductive layer PL2a in the third direction DR3. The second power source conductive layer PL2b may constitute the second power source line PL2 described with reference to FIG. 4 or the like together with the first power source conductive layer PL2a.

The gate electrode GE and the second power source conductive layer PL2b may be formed of a single layer or a multilayer made of molybdenum (Mo), copper (Cu), aluminum (Al), chromium (Cr), gold (Au), titanium (Ti), nickel (Ni), neodymium (Nd), indium (In), tin (Sn), and/or oxides and/or alloys thereof. For example, the gate electrode GE and the second power source conductive layer PL2b may be formed of a multilayer in which titanium (Ti), copper (Cu), and/or indium tin oxide (ITO) are sequentially or repeatedly stacked.

An interlayer insulating layer ILD may be provided on the gate electrode GE and the second power source conductive layer PL2b. For example, the interlayer insulating layer ILD may be provided between the gate electrode GE and the first and second transistor electrodes TE1 and TE2. In addition, the interlayer insulating layer ILD may be provided between the second power source conductive layer PL2b and a third power source conductive layer PL2c.

The interlayer insulating layer ILD may be formed of a single layer or a multilayer, and may include one or more suitable inorganic materials such as silicon oxide (SiOx), silicon nitride (SiNx), silicon oxynitride (SiOxNy), aluminum nitride (AINx), aluminum oxide (AlOx), zirconium oxide (ZrOx), hafnium oxide (HfOx), and/or titanium oxide (TiOx).

The first and second transistor electrodes TE1 and TE2 of the transistor M and the third power source conductive layer PL2c may be provided on the interlayer insulating layer ILD. The first and second transistor electrodes TE1 and TE2 and the third power source conductive layer PL2c may be provided on the same layer (e.g., on the same level). For example, the first and second transistor electrodes TE1 and TE2 and the third power source conductive layer PL2c may be simultaneously (or concurrently) formed in the same process, but the disclosure is not limited thereto.

The first and second transistor electrodes TE1 and TE2 may be provided to overlap the semiconductor pattern SCP in the third direction DR3. The first and second transistor electrodes TE1 and TE2 may be electrically connected to the semiconductor pattern SCP. For example, the first transistor electrode TE1 may be electrically connected to the first region of the semiconductor pattern SCP through a contact hole penetrating the interlayer insulating layer ILD. Also, the first transistor electrode TE1 may be electrically connected to the lower conductive layer BML through a contact hole penetrating the interlayer insulating layer ILD and the buffer layer BFL. The second transistor electrode TE2 may be electrically connected to the second region of the semiconductor pattern SCP through a contact hole penetrating the interlayer insulating layer ILD. According to one or more embodiments, one of the first and second transistor electrodes TE1 and TE2 may be a source electrode and the other may be a drain electrode.

The third power source conductive layer PL2c may be provided to overlap the first power source conductive layer PL2a and/or the second power source conductive layer PL2b in the third direction DR3. The third power source conductive layer PL2c may be electrically connected to the first power source conductive layer PL2a and/or the second power source conductive layer PL2b. For example, the third power source conductive layer PL2c may be electrically connected to the first power source conductive layer PL2a through a contact hole penetrating the interlayer insulating layer ILD and the buffer layer BFL. Also, the third power source conductive layer PL2c may be electrically connected to the second power source conductive layer PL2b through a contact hole penetrating the interlayer insulating layer ILD. The third power source conductive layer PL2c may constitute the second power source line PL2 described with reference to FIG. 4 or the like, together with the first power source conductive layer PL2a and/or the second power source conductive layer PL2b.

The first and second transistor electrodes TE1 and TE2 and the third power source conductive layer PL2c may be formed of a single layer or a multilayer made of molybdenum (Mo), copper (Cu), aluminum (Al), chromium (Cr), gold (Au), titanium ( Ti), nickel (Ni), neodymium (Nd), indium (In), tin (Sn), and/or oxides and/or alloys thereof.

A passivation layer PSV may be provided on the first and second transistor electrodes TE1 and TE2 and the third power source conductive layer PL2c. The passivation layer PSV may be formed of a single layer or a multilayer, and may include one or more suitable inorganic materials such as silicon oxide (SiOx), silicon nitride (SiNx), silicon oxynitride (SiOxNy), aluminum nitride (AINx), aluminum oxide (AlOx), zirconium oxide (ZrOx), hafnium oxide (HfOx), and/or titanium oxide (TiOx).

A via layer VIA may be provided on the passivation layer PSV. The via layer VIA may be formed of an organic material in order to planarize (or substantially planarize) a step difference on a surface. For example, the via layer VIA may include an organic material such as an acrylate resin, an epoxy resin, a phenolic resin, a polyamide resin, a polyimide resin, a polyester resin, a polyphenylenesulfide resin, and/or benzocyclobutene (BCB). However, the disclosure is not necessarily limited thereto, and the via layer VIA may include one or more suitable inorganic materials such as silicon oxide (SiOx), silicon nitride (SiNx), silicon oxynitride (SiOxNy), aluminum nitride (AINx), aluminum oxide (AlOx), zirconium oxide (ZrOx), hafnium oxide (HfOx), and/or titanium oxide (TiOx).

The partition walls WL may be provided on the via layer VIA. The partition walls WL may form a set or predetermined step difference to easily or suitably align the light emitting elements LD in the emission area EA.

The partition walls WL may have various suitable shapes according to embodiments. In one or more embodiments, the partition walls WL may have a shape protruding from the base layer BSL in the third direction DR3. In some embodiments, the partition walls WL may be formed to have an inclined surface inclined at a set or predetermined angle with respect to the base layer BSL. However, the disclosure is not necessarily limited thereto, and the partition walls WL may have a sidewall having a curved surface or a stepped shape. For example, the partition walls WL may have a cross-section such as a semi-circle or semi-ellipse shape.

The partition walls WL may include at least one organic material and/or inorganic material. For example, the partition walls WL may include an organic material such as an acrylate resin, an epoxy resin, a phenolic resin, a polyamide resin, a polyimide resin, a polyester resin, a polyphenylenesulfide resin, and/or benzocyclobutene (BCB). However, the disclosure is not necessarily limited thereto, and the partition walls WL may include one or more suitable inorganic materials such as silicon oxide (SiOx), silicon nitride (SiNx), silicon oxynitride (SiOxNy), aluminum nitride (AINx), aluminum oxide (AlOx), zirconium oxide (ZrOx), hafnium oxide (HfOx), and/or titanium oxide (TiOx).

The first to fourth alignment electrodes AEL1 to AEL4 and the root alignment electrode REL may be provided on the via layer VIA and the partition walls WL. The first to fourth alignment electrodes AEL1 to AEL4 may at least partially cover side surfaces and/or top surfaces of the partition walls WL. The first to fourth alignment electrodes AEL1 to AEL4 provided on the partition walls WL may have a shape corresponding to the partition walls WL. For example, the first to fourth alignment electrodes AEL1 to AEL4 provided on the partition walls WL may include an inclined surface or curved surface having a shape corresponding to the shape of the partition walls WL. In this case, the partition walls WL and the first to fourth alignment electrodes AEL1 to AEL4 may be reflective members that reflect light emitted from the light emitting elements LD and guide the light toward the front of the pixel PXL, for example, the third direction DR3. Therefore, light output efficiency of the display panel PNL may be improved.

The first to fourth alignment electrodes AEL1 to AEL4 and the root alignment electrode REL may include at least one conductive material. For example, the first to fourth alignment electrodes AEL1 to AEL4 and the root alignment electrode REL may include at least one of suitable metal materials such as silver (Ag), magnesium (Mg), aluminum (Al), platinum (Pt), palladium (Pd), gold (Au), nickel (Ni), neodymium (Nd), iridium (Ir), chromium (Cr), titanium (Ti), molybdenum (Mo), copper (Cu), and/or alloys thereof, conductive oxides such as indium tin oxide (ITO), indium zinc oxide (IZO), indium tin zinc oxide (ITZO), aluminum zinc oxide (AZO), gallium zinc oxide (GZO), zinc tin oxide (ZTO), and/or gallium tin oxide (GTO), and/or conductive polymers such as PEDOT, but the disclosure is not limited thereto.

A first insulating layer INS1 may be provided on the first to fourth alignment electrodes AEL1 to AEL4 and the root alignment electrode REL. The first insulating layer INS1 may be formed of a single layer or a multilayer, and may include one or more suitable inorganic materials such as silicon oxide (SiOx), silicon nitride (SiNx), silicon oxynitride (SiOxNy), aluminum nitride (AINx), aluminum oxide (AlOx), zirconium oxide (ZrOx), hafnium oxide (HfOx), and/or titanium oxide (TiOx).

The first bank BNK1 may be provided on the first insulating layer INS1. The first bank BNK1 may include an opening overlapping the emission area EA. The opening of the first bank BNK1 may provide a space for the light emitting elements LD to be provided in the step (or act) of supplying the light emitting elements LD to each of the pixels PXL. For example, a desired type (or kind) and/or amount of light emitting element ink may be supplied to the space partitioned by the opening of the first bank BNK1.

The first bank BNK1 may include an organic material such as an acrylate resin, an epoxy resin, a phenolic resin, a polyamide resin, a polyimide resin, a polyester resin, a polyphenylenesulfide resin, and/or benzocyclobutene (BCB). However, the disclosure is not necessarily limited thereto, and the first bank BNK1 may include one or more suitable inorganic materials such as silicon oxide (SiOx), silicon nitride (SiNx), silicon oxynitride (SiOxNy), aluminum nitride (AINx), aluminum oxide (AlOx), zirconium oxide (ZrOx), hafnium oxide (HfOx), and/or titanium oxide (TiOx).

The light emitting elements LD (for example, the first light emitting element LD1 and the fourth light emitting element LD4) may be provided on first insulating layer INS1. The light emitting elements LD may be provided in the opening of the first bank BNK1 to be provided between the partition walls WL.

The light emitting elements LD may be prepared in a dispersed form in the light emitting element ink, and may be supplied to each of the pixels PXL by an inkjet printing method and/or the like. For example, the light emitting elements LD may be dispersed in a volatile solvent and provided to each of the pixels PXL. Subsequently, as described above, when the alignment signals are supplied to the alignment electrodes AEL, the light emitting elements LD may be aligned based on an electric field formed between the alignment electrodes AEL (for example, between the first alignment electrode AEL1 and the second alignment electrode AEL2, or between the third alignment electrode AEL3 and the fourth alignment electrode AEL4). After the light emitting elements LD are aligned, the light emitting elements LD may be stably or suitably arranged by volatilizing the solvent or removing the solvent by other suitable methods.

A second insulating layer INS2 may be provided on the light emitting elements LD. For example, the second insulating layer INS2 may be partially provided on the light emitting elements LD so that first and second ends EP1 and EP2 of the light emitting elements LD are exposed. When the second insulating layer INS2 is formed on the light emitting elements LD after the light emitting elements LD are aligned, it is possible to prevent or reduce separation of the light emitting elements LD from the aligned positions.

The second insulating layer INS2 may include an organic material such as an acrylic resin, an epoxy resin, a phenolic resin, a polyamide resin, a polyimide resin, a polyester resin, a polyphenylenesulfide resin, and/or benzocyclobutene (BCB). However, the disclosure is not necessarily limited thereto, and the second insulating layer INS2 may include one or more suitable inorganic materials such as silicon oxide (SiOx), silicon nitride (SiNx), silicon oxynitride (SiOxNy), aluminum nitride (AINx), aluminum oxide (AlOx), zirconium oxide (ZrOx), hafnium oxide (HfOx), and/or titanium oxide (TiOx).

The connection electrodes ELT may be provided on the first and second ends EP1 and EP2 of the light emitting elements LD exposed by the second insulating layer INS2.

The first connection electrode ELT1 may be directly provided on first ends EP1 of the first light emitting elements LD1 to be in contact with the first ends EP1 of the first light emitting elements LD1.

The second connection electrode ELT2 may be directly provided on the second ends EP2 of the first light emitting elements LD1 to be in contact with the second ends EP2 of the first light emitting elements LD1. For example, the second connection electrode ELT2 may be directly provided on first ends EP1 of the second light emitting elements LD2 to be in contact with the first ends EP1 of the second light emitting elements LD2. The second connection electrode ELT2 may electrically connect the second ends EP2 of the first light emitting elements LD1 and the first ends EP1 of the second light emitting elements LD2.

In one or more embodiments, the third connection electrode ELT3 may be directly provided on the second ends EP2 of the second light emitting elements LD2 to be in contact with the second ends EP2 of the second light emitting elements LD2. The third connection electrode ELT3 may be directly provided on first ends EP1 of the third light emitting elements LD3 to be in contact with the first ends EP1 of the third light emitting elements LD3. For example, the third connection electrode ELT3 may electrically connect the second ends EP2 of the second light emitting elements LD2 and the first ends EP1 of the third light emitting elements LD3.

The fourth connection electrode ELT4 may be directly provided on the second ends EP2 of the third light emitting elements LD3 to be in contact with the second ends EP2 of the third light emitting elements LD3. The fourth connection electrode ELT4 may be directly provided on first ends EP1 of the fourth light emitting elements LD4 to be in contact with the first ends EP1 of the fourth light emitting elements LD4. For example, the fourth connection electrode ELT4 may electrically connect the second ends EP2 of the third light emitting elements LD3 and the first ends EP1 of the fourth light emitting elements LD4.

In one or more embodiments, the fifth connection electrode ELT5 may be directly provided on the second ends EP2 of the fourth light emitting elements LD4 to be in contact with the second ends EP2 of the fourth light emitting elements LD4.

The first connection electrode ELT1 may be electrically connected to the first transistor electrode TE1 of the transistor M through the first contact portion CNT1 penetrating the first insulating layer INS1. The fifth connection electrode ELT5 may be electrically connected to the third power source conductive layer PL2c through the second contact portion CNT2 penetrating the first insulating layer INS1.

In one or more embodiments, the connection electrodes ELT may be composed of a plurality of conductive layers. For example, as shown in FIGS. 9 and 10, the first connection electrode ELT1, the third connection electrode ELT3, and the fifth connection electrode ELT5 may be provided on the same layer. In some embodiments, the second connection electrode ELT2 and the fourth connection electrode ELT4 may be provided on the same layer. The first connection electrode ELT1, the third connection electrode ELT3, and the fifth connection electrode ELT5 may be provided on the first insulating layer INS1. A third insulating layer INS3 may be provided on the first connection electrode ELT1, the third connection electrode ELT3, and the fifth connection electrode ELT5. The third insulating layer INS3 may be provided between the first connection electrode ELT1 and the second connection electrode ELT2. The third insulating layer INS3 may be provided between the fourth connection electrode ELT4 and the fifth connection electrode ELT5. As such, when the third insulating layer INS3 is provided between the connection electrodes ELT made of different conductive layers, the connection electrodes ELT may be stably or suitably separated by the third insulating layer INS3, and thus electrical stability between the first and second ends EP1 and EP2 of the light emitting element LD can be secured or improved.

However, the disclosure is not limited to the above-described examples. In one or more other embodiments, the connection electrodes ELT may be composed of the same conductive layer (e.g., may be formed on the same level and/or of the same conductive material). For example, the first to fifth connection electrodes ELT1 to ELT5 may be provided on the same layer. For example, the first to fifth connection electrodes ELT1 to ELT5 may be simultaneously (or concurrently) formed in the same process. In this way, when the connection electrodes ELT are simultaneously (or concurrently) formed, the number of masks may be reduced and the manufacturing process may be simplified.

The third insulating layer INS3 may be formed of a single layer or a multilayer, and may include one or more suitable inorganic materials such as silicon oxide (SiOx), silicon nitride (SiNx), silicon oxynitride (SiOxNy), aluminum nitride (AINx), aluminum oxide (AlOx), zirconium oxide (ZrOx), hafnium oxide (HfOx), and/or titanium oxide (TiOx).

The connection electrodes ELT may be formed of one or more suitable transparent conductive materials, respectively. Accordingly, light emitted from the first and second ends EP1 and EP2 of the light emitting elements LD may pass through the connection electrodes ELT and be emitted to outside of the display panel PNL.

A fourth insulating layer INS4 may be provided on the third insulating layer INS3, the first bank BNK1, the second connection electrode ELT2, and the fourth connection electrode ELT4. The fourth insulating layer INS4 may protect individual components from external influences. The fourth insulating layer INS4 may be formed of a single layer or a multilayer, and may include one or more suitable inorganic materials such as silicon oxide (SiOx), silicon nitride (SiNx), silicon oxynitride (SiOxNy), aluminum nitride (AINx), aluminum oxide (AlOx), zirconium oxide (ZrOx), hafnium oxide (HfOx), and/or titanium oxide (TiOx).

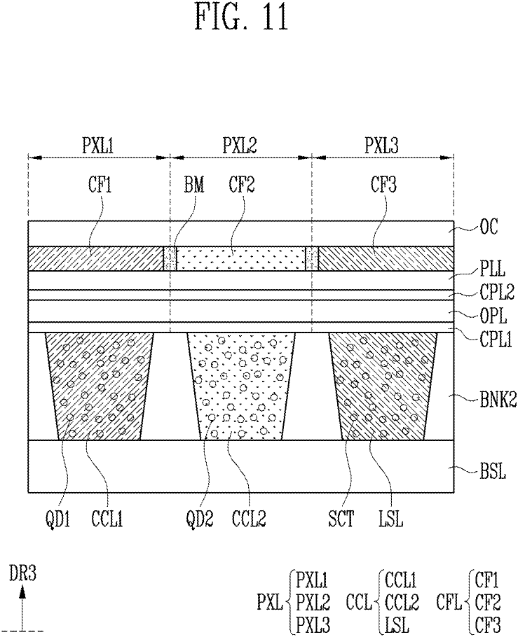

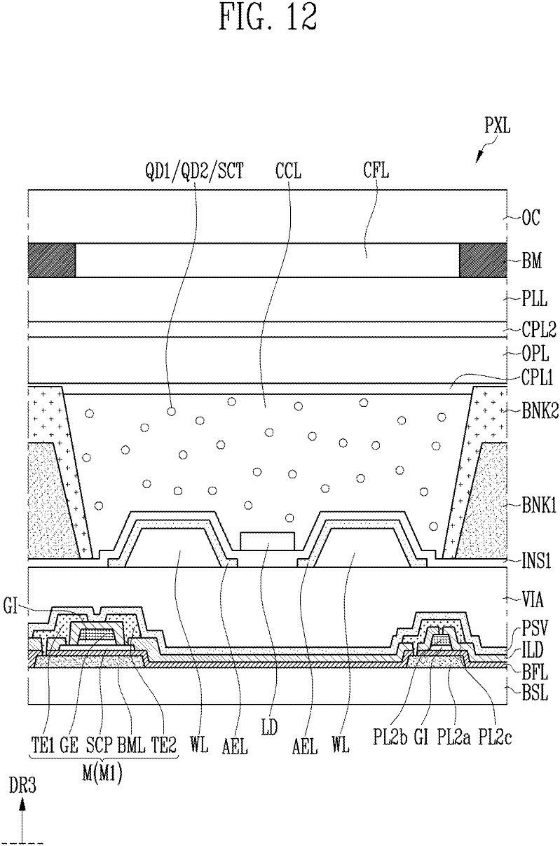

FIG. 11 is a cross-sectional view illustrating first to third pixels according to one or more embodiments. FIG. 12 is a cross-sectional view of a pixel according to one or more embodiments.

FIG. 11 shows a second bank BNK2, a color conversion layer CCL, an optical layer OPL, and/or a color filter layer CFL. In FIG. 11, components other than the base layer BSL of FIGS. 7 to 10 are not shown for convenience of description. FIG. 12 is a more detailed diagram illustrating a stacked structure of a pixel PXL in relation to the second bank BNK2, the color conversion layer CCL, the optical layer OPL, and/or the color filter layer CFL. For convenience of description, some electrode layers and insulating layers are not shown in FIG. 12.

Referring to FIGS. 11 and 12, the second bank BNK2 may be provided between or at a boundary between first to third pixels PXL1, PXL2, and PXL3, and may include an opening overlapping each of the first to third pixels PXL1, PXL2, and PXL3. The opening of the second bank BNK2 may provide a space in which the color conversion layer CCL may be provided. For example, a desired type (or kind) and/or amount of the color conversion layer CCL may be supplied to the space partitioned by the opening of the second bank BNK2.

The second bank BNK2 may include an organic material such as an acrylate resin, an epoxy resin, a phenolic resin, a polyamide resin, a polyimide resin, a polyester resin, a polyphenylenesulfide resin, and/or benzocyclobutene (BCB). However, the disclosure is not necessarily limited thereto, and the second bank BNK2 may include one or more suitable inorganic materials such as silicon oxide (SiOx), silicon nitride (SiNx), silicon oxynitride (SiOxNy), aluminum nitride (AINx), aluminum oxide (AlOx), zirconium oxide (ZrOx), hafnium oxide (HfOx), and/or titanium oxide (TiOx).

According to one or more embodiments, the second bank BNK2 may include at least one light blocking and/or reflective material. Accordingly, light leakage between adjacent pixels PXL may be prevented or reduced. For example, the second bank BNK2 may include a black pigment, but is not limited thereto.

The color conversion layer CCL may be provided on light emitting elements LD in the opening of the second bank BNK2. The color conversion layer CCL may include a first color conversion layer CCL1 provided in the first pixel PXL1, a second color conversion layer CCL2 provided in the second pixel PXL2, and a scattering layer LSL provided in the third pixel PXL3.

In one or more embodiments, the first to third pixels PXL1, PXL2, and PXL3 may include light emitting elements LD emitting (e.g., configured to emit) light of the same color. For example, the first to third pixels PXL1, PXL2, and PXL3 may include light emitting elements LD emitting light of the third color (or blue). The color conversion layer CCL including color conversion particles may be provided in each of the first to third pixels PXL1, PXL2, and PXL3 to display a full-color image.

The first color conversion layer CCL1 may include first color conversion particles for converting the light of the third color emitted from the light emitting element LD into light of the first color. For example, the first color conversion layer CCL1 may include a plurality of first quantum dots QD1 dispersed in a set or predetermined matrix material such as a base resin.

In one or more embodiments, when the light emitting element LD is a blue light emitting element emitting blue light and the first pixel PXL1 is a red pixel, the first color conversion layer CCL1 may include first quantum dots QD1 for converting blue light emitted from the blue light emitting element into red light. The first quantum dots QD1 may absorb blue light and shift a wavelength according to energy transition to emit red light. In one or more embodiments, when the first pixel PXL1 is a pixel of a different color, the first color conversion layer CCL1 may include first quantum dots QD1 corresponding to the color of the first pixel PXL1.

The second color conversion layer CCL2 may include second color conversion particles for converting the light of the third color emitted from the light emitting element LD into light of the second color. For example, the second color conversion layer CCL2 may include a plurality of second quantum dots QD2 dispersed in a set or predetermined matrix material such as a base resin.

In one or more embodiments, when the light emitting element LD is a blue light emitting element emitting blue light and the second pixel PXL2 is a green pixel, the second color conversion layer CCL2 may include second quantum dots QD2 for converting blue light emitted from the blue light emitting element into green light. The second quantum dots QD2 may absorb blue light and shift a wavelength according to energy transition to emit green light. In one or more embodiments, when the second pixel PXL2 is a pixel of a different color, the second color conversion layer CCL2 may include second quantum dots QD2 corresponding to the color of the second pixel PXL2.

In one or more embodiments, absorption coefficients of the first quantum dots QD1 and the second quantum dots QD2 may be increased by incident blue light having a relatively short wavelength in the visible light region to the first quantum dots QD1 and the second quantum dots QD2, respectively. Accordingly, the efficiency of light finally emitted from the first pixel PXL1 and the second pixel PXL2 may be improved, and excellent or improved color reproducibility may be secured. In addition, manufacturing efficiency of the display device may be improved by configuring emission units EMU of the first to third pixels PXL1, PXL2, and PXL3 using light emitting elements LD of the same color (for example, blue light emitting elements).

The scattering layer LSL may be provided to efficiently or suitable use (utilize) the light of the third color (or blue) emitted from the light emitting element LD. For example, when the light emitting element LD is a blue light emitting element emitting blue light and the third pixel PXL3 is a blue pixel, the scattering layer LSL may include at least one type (or kind) of scattering material SCT in order to efficiently or suitably use the light emitted from the light emitting element LD. For example, the scattering material SCT of the scattering layer LSL may include at least one of barium sulfate (BaSO₄), calcium carbonate (CaCO₃), titanium oxide (TiO₂), silicon oxide (SiO₂), aluminum oxide (Al₂O₃), or zinc oxide (ZnO). In one or more embodiments, the scattering material SCT is not provided (e.g., is excluded) only in the third pixel PXL3, and may be selectively included in the first color conversion layer CCL1 or the second color conversion layer CCL2. According to one or more embodiments, the scattering material SCT may be omitted (e.g., may not be provided) and the scattering layer LSL made of a transparent polymer may be provided.

A first capping layer CPL1 may be provided on the color conversion layer CCL. The first capping layer CPL1 may be provided over the first to third pixels PXL1, PXL2, and PXL3. The first capping layer CPL1 may cover the color conversion layer CCL. The first capping layer CPL1 may prevent or reduce the penetration of impurities such as moisture and/or air from outside to damage and/or contaminate the color conversion layer CCL.

The first capping layer CPL1 may be an inorganic layer, and may include silicon nitride (SiNx), aluminum nitride (AINx), titanium nitride (TiNx), silicon oxide (SiOx), aluminum oxide (AlOx), titanium oxide (TiOx), silicon oxycarbide (SiOxCy), silicon oxynitride (SiOxNy), and/or the like.

The optical layer OPL may be provided on the first capping layer CPL1. The optical layer OPL may improve light extraction efficiency by recycling light provided from the color conversion layer CCL by total reflection. To this end, the optical layer OPL may have a relatively low refractive index compared to the color conversion layer CCL. For example, the refractive index of the color conversion layer CCL may be about 1.6 to 2.0, and the refractive index of the optical layer OPL may be about 1.1 to 1.3.

A second capping layer CPL2 may be provided on the optical layer OPL. The second capping layer CPL2 may be provided over the first to third pixels PXL1, PXL2, and PXL3. The second capping layer CPL2 may cover the optical layer OPL. The second capping layer CPL2 may prevent or reduce the penetration of impurities such as moisture and/or air from outside to damage and/or contaminate the optical layer OPL.

The second capping layer CPL2 may be an inorganic layer, and may include silicon nitride (SiNx), aluminum nitride (AINx), titanium nitride (TiNx), silicon oxide (SiOx), aluminum oxide (AlOx), titanium oxide (TiOx), silicon oxycarbide (SiOxCy), silicon oxynitride (SiOxNy), and/or the like.

A planarization layer PLL may be provided on the second capping layer CPL2. The planarization layer PLL may be provided over the first to third pixels PXL1, PXL2, and PXL3.

The planarization layer PLL may include an organic material such as an acrylic resin, an epoxy resin, a phenolic resin, a polyamide resin, a polyimide resin, a polyester resin, a polyphenylenesulfide resin, and/or benzocyclobutene (BCB). However, the disclosure is not necessarily limited thereto, and the planarization layer PLL may include one or more suitable inorganic materials such as silicon oxide (SiOx), silicon nitride (SiNx), silicon oxynitride (SiOxNy), aluminum nitride (AINx), aluminum oxide (AlOx), zirconium oxide (ZrOx), hafnium oxide (HfOx), and/or titanium oxide (TiOx).

The color filter layer CFL may be provided on the planarization layer PLL. The color filter layer CFL may include color filters CF1, CF2, and CF3 matching the colors of the pixels PXL. A full-color image may be displayed by providing the color filters CF1, CF2, and CF3 matching the colors of the first to third pixels PXL1, PXL2, and PXL3, respectively.

The color filter layer CFL may include a first color filter CF1 provided in the first pixel PXL1 to selectively transmit light emitted from the first pixel PXL1, a second color filter CF2 provided in the second pixel PXL2 to selectively transmit light emitted from the second pixel PXL2, and a third color filter CF3 provided in the third pixel PXL3 to selectively transmit light emitted from the third pixel PXL3.

In one or more embodiments, the first color filter CF1, the second color filter CF2, and the third color filter CF3 may be a red color filter, a green color filter, and a blue color filter, respectively, but the disclosure is not limited thereto. Hereinafter, when any color filter among the first color filter CF1, the second color filter CF2, and the third color filter CF3 is arbitrarily referred to, or two or more types of color filters are generically referred to, they will be referred to as “color filter CF” or “color filters CF”.

The first color filter CF1 may overlap the first color conversion layer CCL1 in the third direction (Z-axis direction). The first color filter CF1 may include a color filter material for selectively transmitting light of the first color (or red). For example, when the first pixel PXL1 is a red pixel, the first color filter CF1 may include a red color filter material.

The second color filter CF2 may overlap the second color conversion layer CCL2 in the third direction (Z-axis direction). The second color filter CF2 may include a color filter material for selectively transmitting light of the second color (or green). For example, when the second pixel PXL2 is a green pixel, the second color filter CF2 may include a green color filter material.

The third color filter CF3 may overlap the scattering layer LSL in the third direction (Z-axis direction). The third color filter CF3 may include a color filter material for selectively transmitting light of the third color (or blue). For example, when the third pixel PXL3 is a blue pixel, the third color filter CF3 may include a blue color filter material.

According to one or more embodiments, a light blocking layer BM may be further provided between the first to third color filters CF1, CF2, and CF3. As such, when the light blocking layer BM is formed between the first to third color filters CF1, CF2, and CF3, color mixing defects recognized from the front or side of the display device may be prevented or reduced. The material of the light blocking layer BM is not particularly limited, and may be composed of one or more suitable light blocking materials. For example, the light blocking layer BM may be implemented by stacking the first to third color filters CF1, CF2, and CF3 on each other.

An overcoat layer OC may be provided on the color filter layer CFL. The overcoat layer OC may be provided over the first to third pixels PXL1, PXL2, and PXL3. The overcoat layer OC may cover lower members including the color filter layer CFL. The overcoat layer OC may prevent or reduce the penetration of moisture and/or air into the above-described lower members. In addition, the overcoat layer OC may protect the above-described lower members from foreign substances such as dust.

The overcoat layer OC may include an organic material such as an acrylic resin, an epoxy resin, a phenolic resin, a polyamide resin, a polyimide resin, a polyester resin, a polyphenylenesulfide resin, and/or benzocyclobutene (BCB). However, the disclosure is not necessarily limited thereto, and the overcoat layer OC may include one or more suitable inorganic materials such as silicon oxide (SiOx), silicon nitride (SiNx), silicon oxynitride (SiOxNy), aluminum nitride (AINx), aluminum oxide (AlOx), zirconium oxide (ZrOx), hafnium oxide (HfOx), and/or titanium oxide (TiOx).

According to the embodiments of the disclosure, the display device in which a manufacturing process is simplified and noise with respect to an electrical signal and resistance of a wiring are reduced may be provided.

As described above, the embodiments of the disclosure have been disclosed through the detailed description and the drawings. However, those skilled in the art or those of ordinary skill in the art will appreciate that various modifications and changes are possible without departing from the spirit and technical scope of the disclosure as set forth in the claims below.

Therefore, the technical protection scope of the disclosure is not limited to the detailed description described in the specification, but should be determined by the appended claims and their equivalents.

What is claimed is:

1. A display device comprising:
pixels,
wherein the pixels comprise:
alignment electrodes on a base layer;
a light emitting element on the alignment electrodes; and
connection electrodes electrically connected to the light emitting element,
wherein the connection electrodes are electrically connected to some of the alignment electrodes through contact portions, and
wherein a number of the contact portions defined in each of the pixels is less than a number of the alignment electrodes.

2. The display device of claim 1, wherein the connection electrodes comprise an anode connection electrode and a cathode connection electrode,
wherein the light emitting element is electrically connected between the anode connection electrode and the cathode connection electrode, and
wherein the alignment electrodes are electrically connected to at least one of the anode connection electrode and the cathode connection electrode.

3. The display device of claim 2, wherein the anode connection electrode and the cathode connection electrode are formed from a same conductive layer.

4. The display device of claim 2, wherein when the light emitting element emits light, an anode signal or a cathode signal is provided to the alignment electrodes.

5. The display device of claim 2, wherein the alignment electrodes comprise a first alignment electrode, a second alignment electrode, a third alignment electrode, a fourth alignment electrode, and a root alignment electrode, and
wherein the root alignment electrode, the second alignment electrode, and the third alignment electrode are integrally formed and are electrically connected to each other.

6. The display device of claim 5, wherein a portion of the cathode connection electrode is electrically connected to the root alignment electrode, and another portion of the cathode connection electrode is electrically connected to the fourth alignment electrode.

7. The display device of claim 6, wherein the second alignment electrode, the third alignment electrode, and the fourth alignment electrode are electrically connected to each other.

8. The display device of claim 2, wherein when the light emitting element emits light, the alignment electrodes are not in a floating state.

9. The display device of claim 5, wherein when the light emitting element emits light, the alignment electrodes are not in a floating state, an anode signal flows through the first alignment electrode, and a cathode signal flows through the second alignment electrode, the third alignment electrode, and the fourth alignment electrode.

10. The display device of claim 1, wherein the connection electrodes comprise a first connection electrode, a second connection electrode, a third connection electrode, a fourth connection electrode, and a fifth connection electrode,
wherein the alignment electrodes comprise a first alignment electrode, a second alignment electrode, a third alignment electrode, and a fourth alignment electrode,
wherein the light emitting element comprises a first light emitting element, a second light emitting element, a third light emitting element, and a fourth light emitting element,
wherein the first light emitting element is electrically connected between the first connection electrode and the second connection electrode, and is aligned between the first alignment electrode and the second alignment electrode,
wherein the second light emitting element is electrically connected between the second connection electrode and the third connection electrode, and is aligned between the first alignment electrode and the second alignment electrode,
wherein the third light emitting element is electrically connected between the third connection electrode and the fourth connection electrode, and is aligned between the third alignment electrode and the fourth alignment electrode, and
wherein the fourth light emitting element is electrically connected between the fourth connection electrode and the fifth connection electrode, and is aligned between the third alignment electrode and the fourth alignment electrode.

11. The display device of claim 10, wherein the contact portions comprise a first contact portion, a second contact portion, and a third contact portion,
wherein the first connection electrode is electrically connected to the first alignment electrode through the first contact portion,
wherein the fifth connection electrode is electrically connected to the second alignment electrode and the third alignment electrode through the second contact portion, and is electrically connected to the fourth alignment electrode through the third contact portion, and
wherein the first connection electrode is configured to supply an anode signal to the light emitting element and the fifth connection electrode is configured to supply a cathode signal to the light emitting element so that the light emitting element emits light.

12. The display device of claim 11, wherein the fifth connection electrode overlaps the second contact portion and the third contact portion in a plan view.

13. The display device of claim 12, wherein the first contact portion, the second contact portion, and the third contact portion are arranged parallel to a direction in which the first alignment electrode, the second alignment electrode, the third alignment electrode, and the fourth alignment electrode are adjacent to each other.

14. The display device of claim 11, wherein when the light emitting element emits light, the anode signal provided through the first connection electrode is supplied to the light emitting element and the first alignment electrode, and the cathode signal provided through the fifth connection electrode is supplied to the light emitting element, the second alignment electrode, the third alignment electrode, and the fourth alignment electrode.

15. The display device of claim 11, wherein the first connection electrode and the fifth connection electrode are formed from a same conductive layer.

16. The display device of claim 10, wherein the fifth connection electrode is not electrically connected to the fourth alignment electrode.

17. The display device of claim 16, wherein when the light emitting element emits light, an anode signal is supplied to the first alignment electrode, and a cathode signal is supplied to the second alignment electrode and the third alignment electrode.

18. The display device of claim 10, wherein the alignment electrodes comprise a bridge alignment electrode, and
wherein the bridge alignment electrode electrically connects the fourth alignment electrode and an adjacent alignment electrode of an adjacent pixel to each other.

19. The display device of claim 18, wherein when the light emitting element emits light, an anode signal is supplied to the first alignment electrode and the fourth alignment electrode, and a cathode signal is supplied to the second alignment electrode and the third alignment electrode.

20. A display device comprising:
alignment electrodes on a base layer;
a light emitting element between the alignment electrodes; and
connection electrodes configured to supply an anode signal or a cathode signal to the light emitting element,
wherein when the light emitting element emits light, the alignment electrodes are not in a floating state and are supplied with the anode signal or the cathode signal.
